(19) United States
(12) Patent Application Publication
(10) Pub. No.: US 2026/0052855 A1
(43) Pub. Date: Feb. 19, 2026

(54) Display Apparatus

(71) Applicant: LG Display Co., Ltd., Seoul (KR)

(72) Inventors: Sangmoo Song, Paju-si (KR); Intae Ko, Paju-si (KR); Jinuk Lee, Paju-si (KR)

(21) Appl. No.: 19/232,457

(22) Filed: Jun. 9, 2025

(30) Foreign Application Priority Data
Aug. 19, 2024 (KR) 10-2024-0110526

(51) Int. Cl. H10K 59/124; H10K 59/123

(52) U.S. Cl. CPC H10K 59/124; H10K 59/123

(57) ABSTRACT

A display apparatus includes a substrate including a display area and a non-display area surrounding the display area, a thin film transistor disposed on the substrate, a first protective layer on the thin film transistor, a connection electrode electrically connected to the thin film transistor on the first protective layer, a second protective layer on the connection electrode, a planarization layer on the second protective layer, and an anode electrode on the planarization layer, wherein an upper surface of the second protective layer includes a first inclined surface that is inclined with respect to an upper surface of the first protective layer, and the planarization layer covers the first inclined surface of the second protective layer.

### CROSS REFERENCE TO RELATED APPLICATION

The present application claims priority to Republic of Korea Patent Application No. 10-2024-0110526, filed on Aug. 19, 2024, which is incorporated by reference in its entirety.

### BACKGROUND

### Field of Technology

The present specification relates to a display apparatus.

### Description of the Related Art

As the information society develops, various demands for display apparatuses for displaying images are increasing, and various types of display apparatuses, such as a liquid crystal display (LCD) apparatus and an organic light emitting diode (OLED) display apparatus, are being utilized.

Among the display apparatuses, there is an advantage in that the OLED display apparatus as the self-luminous type has a wider viewing angle and a high contrast ratio and is lighter and thinner and has less power consumption than the LCD apparatus because it does not require a separate backlight. In addition, there is an advantage in that the OLED display apparatus can drive at a low voltage, have a fast response time, and especially have the inexpensive manufacturing cost.

The OLED display apparatus can also be applied to display apparatuses mounted on vehicles. Among display apparatuses installed on a vehicle, display apparatuses in front of a driver's seat and a front passenger's seat need to limit a viewing angle of a driver according to driving situations of the driver. The display apparatus needs to limit a viewing angle according to a user's needs for privacy and information protection.

### SUMMARY

The present specification is directed to providing a display apparatus in which an inclined surface has a flat surface even when the inclined surface is formed.

The present specification is also directed to providing a display apparatus in which a conductive layer disposed on an inclined surface is more smoothly deposited.

The present specification is also directed to providing a display apparatus in which different images can be provided according to a user's location on one screen.

The present specification is also directed to providing a display apparatus in which, by depositing a conductive layer more smoothly, it is possible to reduce a defect due to a process and increase the life of the display apparatus.

Objects of the present specification are not limited to the above-described objects, and other technical objects may be inferred from the following embodiments.

According to one embodiment of the present specification, there is provided a display apparatus including: a substrate including a display area and a non-display area that is around the display area; a thin film transistor on the substrate; a first protective layer on the thin film transistor; a connection electrode on the first protective layer, the connection electrode electrically connected to the thin film transistor through the first protective layer; a second protective layer on the connection electrode, the second protective layer having an upper surface that includes a first inclined surface that is tilted with respect to an upper surface of the first protective layer; a planarization layer on the second protective layer, the planarization layer covering the first inclined surface of the second protective layer; and an anode electrode on the planarization layer such that the anode electrode overlaps the first inclined surface of the second protective layer.

According to another embodiment of the present specification, there is provided a display apparatus comprising: a substrate including a display area and a non-display area that is around the display area; a thin film transistor on the substrate; a first protective layer on the thin film transistor; a connection electrode on the first protective layer, the connection electrode electrically connected to the thin film transistor through the first protective layer; a second protective layer on the connection electrode; a third protective layer on the second protective layer, the third protective layer having an upper surface that includes an inclined surface that is tilted with respect to an upper surface of the first protective layer; a planarization layer on the third protective layer, the planarization layer covering the inclined surface of the third protective layer; and an anode electrode on the planarization layer such that the anode electrode overlaps the inclined surface of the third protective layer.

In one embodiment, a display apparatus comprises: a substrate including a display area having a first subpixel and a second subpixel; a first thin film transistor included in the first subpixel and a second thin film transistor included in the second subpixel; a first protective layer on the first thin film transistor and the second thin film transistor; a first organic light emitting element of the first subpixel, the first organic light emitting element electrically connected to the first thin film transistor and tilted at a first angle with respect to an upper surface of the first protective layer such that light is emitted by the first organic light emitting element at the first angle; a second organic light emitting element of the second subpixel, the second organic light emitting element connected to the second thin film transistor and tilted at a second angle with respect to the upper surface of the first protective layer such that light is emitted by the second organic light emitting element at the second angle that is different from the first angle.

In one embodiment, a display apparatus comprises: a substrate including a display area, the display area including a first subpixel having a first emission area and a second subpixel having a second emission area; a first organic light emitting element disposed in the first emission area of the first subpixel; a second organic light emitting element disposed in the second emission area of the second subpixel; a first microlens having a center that is offset from a center of the first emission area of the first subpixel along a first direction in a plan view of the display apparatus; and a second microlens having a center that is offset from a center of the second emission area of the second subpixel along a second direction that is opposite the first direction in the plan view.

Detailed matters of other embodiments are included in the detailed description and accompanying drawings.

According to the embodiments of the present specification, the inclined surface can have a flat surface even when the inclined surface is formed.

According to the embodiments of the present specification, the conductive layer disposed on the inclined surface can be more smoothly deposited.

According to the embodiments of the present specification, different images can be provided according to the user's location on one screen.

According to the embodiments of the present specification, by depositing the conductive layer more smoothly, it is possible to reduce a defect due to the process and increase the life of the display apparatus.

According to the embodiments of the present specification, it is possible to suppress the occurrence of a defect of the display apparatus and a defect due to a process, it is possible to reduce production energy.

However, effects obtainable from the present specification are not limited to the above-described effects, and other effects that are not mentioned will be able to be clearly understood by those skilled in the art to which the present specification pertains based on the following description.

### BRIEF DESCRIPTION OF THE DRAWINGS

FIG. 1 is a plan view of a display apparatus according to one embodiment.

FIG. 2 is an enlarged view of area Q1 in FIG. 1 according to one embodiment.

FIG. 3 is a view illustrating a display panel of FIG. 2 according to one embodiment.

FIG. 4 is a plan view illustrating a pixel arrangement of a display panel according to one embodiment.

FIG. 5 is a cross-sectional view along line V-V′ in FIG. 4 according to one embodiment.

FIG. 6 is an enlarged view of area Q2 in FIG. 5 according to one embodiment.

FIG. 7 is a cross-sectional view of a touch part of FIG. 5 taken at a different angle according to one embodiment.

FIG. 8 is a plan view of a display panel according to one embodiment.

FIG. 9 is a cross-sectional view along line VIII-VII′ in FIG. 8 according to one embodiment.

FIG. 10 is a cross-sectional view along line A-A′ in FIG. 1 according to one embodiment.

FIG. 11 is a cross-sectional view along line B-B′ in FIG. 3 according to one embodiment.

FIG. 12 is a cross-sectional view along line C-C′ in FIG. 3 according to one embodiment.

FIG. 13 is a cross-sectional view of the display apparatus according to another embodiment.

FIG. 14 is an enlarged view of area Q3 in FIG. 13 according to one embodiment.

FIG. 15 is a plan view of a display apparatus according to still another embodiment.

FIG. 16 is an enlarged view of area Q4 in FIG. 15 according to one embodiment.

FIG. 17 is a cross-sectional view along line D-D′ in FIG. 16 according to one embodiment.

FIG. 18 is a cross-sectional view of the display apparatus according to another embodiment.

FIG. 19 is a cross-sectional view of a display apparatus according to yet another embodiment.

### DETAILED DESCRIPTION

Hereinafter, embodiments will be described with reference to the accompanying drawings. In the specification, when a first component (or an area, a layer, a portion, etc.) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

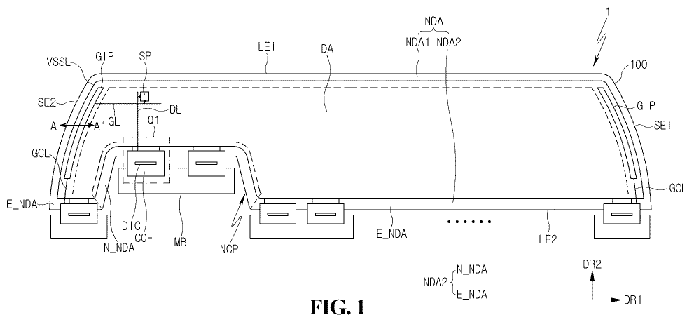

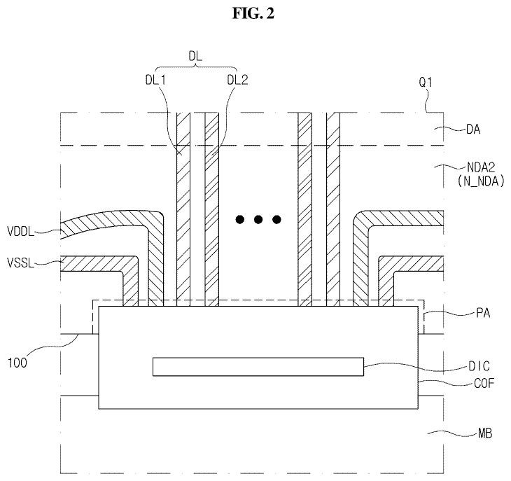

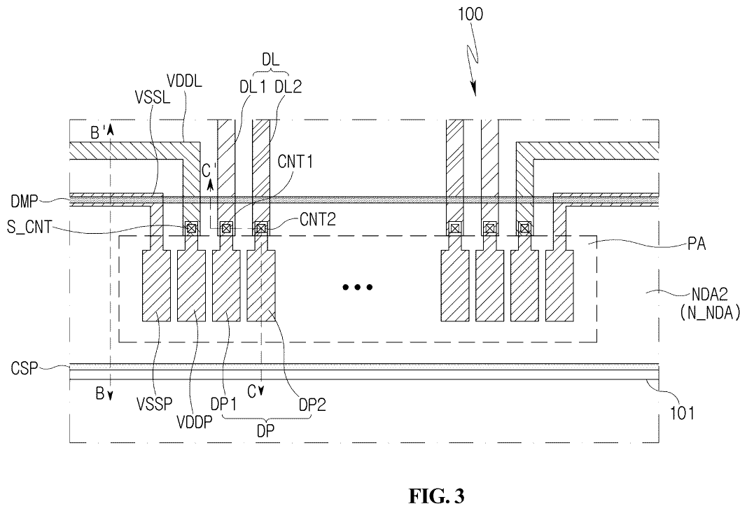

FIG. 1 is a plan view of a display apparatus according to one embodiment. FIG. 2 is an enlarged view of area Q1 in FIG. 1 according to one embodiment. FIG. 3 is a view illustrating a display panel of FIG. 2 according to one embodiment.

FIG. 3 is a view of FIG. 2 from which a flexible film COF, a main board MB, and a drive integrated circuit (IC) DIC are omitted except for the display panel 100. In FIG. 3, for convenience of description, ratios between components are adjusted.

Referring to FIGS. 1 to 3, a display apparatus 1 may be an apparatus including both a display function for displaying a video and a touch sensing function for sensing touch of a user, but is not limited thereto. For example, the display apparatus 1 may include one of the display function of displaying an image and the touch sensing function of sensing a user's touch.

The display apparatus 1 may be an electroluminescent display apparatus or a micro light-emitting diode display apparatus that includes a touch sensor. The electroluminescent display apparatus including the touch sensor may be an organic light-emitting diode (OLED) display apparatus, a quantum-dot light-emitting diode display apparatus, or an inorganic light-emitting diode display apparatus.

The display apparatus 1 according to the present embodiment may be a vehicle display apparatus, but is not limited thereto. For example, the description of the display apparatus 1 may be applied without limitation to the type of the apparatus as long as a display apparatus is an apparatus including a display function.

When the display apparatus 1 according to the present embodiment is a vehicle display apparatus, the display apparatus 1 may include a function of manipulating at least some of various functions of a vehicle, a function of displaying various pieces of information about the vehicle, and the like.

When the display apparatus 1 according to the present embodiment is a vehicle display apparatus, the display apparatus 1 may be disposed on a dashboard of a vehicle. The display apparatus 1 may be disposed across a driver's seat and a front passenger's seat that are disposed at front seats of a vehicle, but is not limited thereto. Both a driver in the driver's seat and a passenger in the front passenger's seat can use the display apparatus 1.

The display apparatus 1 may include a display panel 100. The display panel 100 may include the display area DA and the non-display area NDA.

The display area DA may be an area in which light is emitted to the outside to display a screen. The display area DA may further include a function of sensing a user's touch. In this case, the display area DA may correspond to a touch sensing area, but is not limited thereto.

The display area DA may correspond to the shape of the display panel 100, but is not limited thereto.

A plurality of sub-pixels SP (or pixels) may be disposed in the display area DA. The sub-pixel may be repeatedly disposed in a first direction DR1 and a second direction DR2.

The non-display area NDA may be an area in which light is not emitted to the outside so as not to display a screen. The non-display area NDA may be located around the display area DA. The non-display area NDA may surround the display area DA, but the embodiments of the present specification are not limited thereto. A bezel area of the display apparatus 1 may be defined by the non-display area NDA, but the embodiments of the present specification are not limited thereto.

The display panel 100 may be a rigid display panel, but is not limited thereto. The display panel 100 may be a flexible display panel of which shape may be deformed, such as a foldable, bendable, rollable, or stretchable display panel.

The display panel 100 may include a first long edge LE1, a second long edge LE2, a first short edge SE1, and a second short edge SE2 that form an edge of the display panel 100.

The first long edge LE1 and the second long edge LE2 may extend in a first direction DR1, and the first short edge SE1 and the second short edge SE2 may extend in a direction between the first direction DR1 and a second direction DR2. The first long edge LE1 and the second long edge LE2 may have both ends connected through the first short edge SE1 and the second short edge SE2.

The first long edge LE1 may be disposed at one side of the second long edge LE2 in the second direction DR2. The first long edge LE1 and the second long edge LE2 may extend in parallel, but are not limited thereto.

A length of the first long edge LE1 may be shorter than a length of the second long edge LE2. Accordingly, the first short edge SE1 and the second short edge SE2 may extend in an intersecting direction, but are not limited thereto.

The first direction DR1 and the second direction DR2 may be directions intersecting each other. The first direction DR1 and the second direction DR2 may be orthogonal, but are not limited thereto. The first direction DR1 and the second direction DR2 are provided to clarify the description of the invention, the first direction DR1 and the second direction DR2 are relative, and the embodiments of the present specification are not limited thereto.

In a plan view, the first long edge LE1 may be disposed above the display area DA, and the second long edge LE2 may be disposed under the display area DA.

In a plan view, the first short edge SE1 may be disposed at the right side of the display area DA, and the second short edge SE2 may be disposed at the left side of the display area DA.

The display panel 100 may include a curved notch NCP. The notch NCP may be formed at the second long edge LE2, but is not limited thereto. That is, the second long edge LE2 may entirely extend in the first direction DR1, but may include the notch NCP that is curved toward the first long edge LE1.

Since the notch NCP is disposed, components, such as a handle of a driver's seat, may be disposed on the corresponding portion to maximize the display area DA capable of displaying the screen, thereby improving a user's convenience and improving aesthetic feeling.

The non-display area NDA may include a first non-display area NDA1 disposed along the first long edge LE1, the first short edge SE1, and the second short edge SE2, and a second non-display area NDA2 disposed along the second long edge LE2. The second non-display area NDA2 may be disposed along the second long edge LE2 including the curved notch NCP.

In a plan view, the second non-display area NDA2 may be disposed at a lower side (bottom) of the display area DA, and the first non-display area NDA1 may be disposed at the left, right, and upper (top) sides of the display area DA, but the embodiments of the present specification area not limited thereto.

The second non-display area NDA2 may include a notch non-display area N_NDA disposed around the notch NCP, and an extension non-display area E_NDA disposed around the notch non-display area N_NDA.

The extension non-display area E_NDA may extend from the notch non-display area N_NDA in the first direction DR1. The extension non-display area E_NDA may be disposed between the notch non-display area N_NDA and the first non-display area NDA1. The extension non-display area E_NDA may connect the notch non-display area N_NDA to the first non-display area NDA1.

The second non-display area NDA2 may be disposed at the other side of the display area DA in the second direction DR2. The first non-display area NDA1 may be disposed at one side and the other side of the display area DA in the first direction DR1 and disposed at one side of the display area DA in the second direction DR2.

The display apparatus 1 may further include a pad area PA, a gate driving unit GIP, a main board MB, a flexible film COF, a drive IC DIC, a gate line GL, a data line DL, a low-potential voltage line VSSL, and a high-potential voltage line VDDL.

The pad area PA may overlap the flexible film COF. The pad area PA may be attached to the flexible film COF. That is, the display panel 100 and the flexible film COF may be attached through the pad area PA.

The pad area PA may be disposed in the non-display area NDA. The pad area PA may be disposed in the second non-display area NDA2. The pad area PA may be disposed in each of the notch non-display area N_NDA and the extension non-display area E_NDA.

The pad area PA may include a plurality of pads. The pad area PA may include a low-potential voltage pad VSSP, a high-potential voltage pad VDDP, a first data pad DP1, and a second data pad DP2. The low-potential voltage pad VSSP, the high-potential voltage pad VDDP, the first data pad DP1, and the second data pad DP2 may be disposed in the pad area PA.

However, the embodiments of the present specification are not limited thereto, and the pad area PA disposed in an area that overlaps the flexible films COFs disposed at both ends among the flexible films COFs disposed along the non-display area NDA may further include a gate control pad (not illustrated). The gate control pad (not illustrated) may be connected to the gate driving unit GIP through a gate control line GCL.

The gate driving unit GIP may be disposed in the non-display area NDA. The gate driving unit GIP may be disposed at at least one of one side and the other side of the display area DA in the first direction DR1, but is not limited thereto. In a plan view, the gate driving unit GIP may be disposed at the left side and the other side of the display area DA.

The gate driving unit GIP may be disposed in the first non-display area NDA1. The gate driving unit GIP may be disposed between the low-potential voltage line VSSL and the display area DA in the first non-display area NDA1.

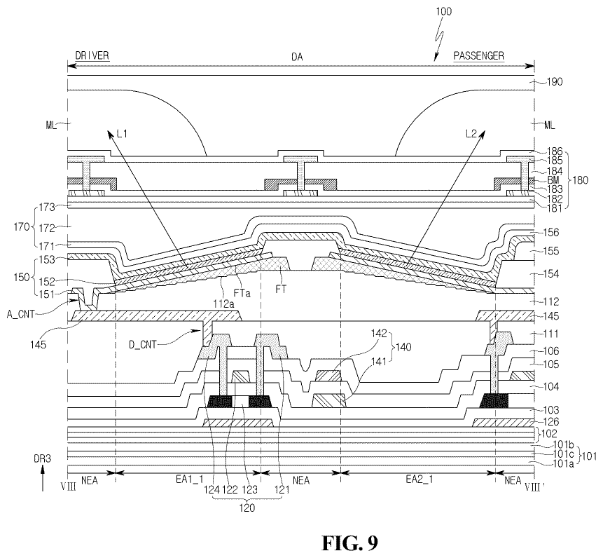

The gate driving unit GIP may include a plurality of transistors 120 (see FIG. 9). The gate driving unit GIP may be connected to the sub-pixel SP (or the pixel) through the gate line GL. The transistors 120 (see FIG. 9) disposed in the gate driving unit GIP may be connected to a sub-pixel SP (or a pixel) through the gate line GL. The gate driving unit GIP may apply a gate signal to each sub-pixel SP (or each pixel) through the gate line GL.

The gate driving unit GIP may receive a gate control signal from the drive IC DIC through the gate control line GCL. The gate driving unit GIP may generate a scan signal and a light-emitting signal (or a light-emitting control signal) based on the gate control signal.

The gate driving unit GIP may include a scan driver and a light-emitting signal driver. The scan driver may generate a scan signal in a row-sequential manner and supply the scan signal to the scan lines in order to drive one or more scan lines connected to each sub-pixel SP (or each pixel) row. The light-emitting signal driver may generate a light-emitting signal in a row-sequential manner and supply the light-emitting signal to light-emitting signal lines in order to drive one or more light-emitting signal lines connected to each sub-pixel SP (or each pixel) row.

The main board MB may be connected to the display panel 100 through the flexible film COF. The main board MB may be electrically connected to the sub-pixel SP (or the pixel) of the display area DA through the flexible film COF. The main board MB may be electrically connected to the flexible film COF. The main board MB and the flexible film COF may be electrically connected through the plurality of pads VSSP, VDDP, and DP.

The main board MB may have various types of components for supplying various signals, such as a gate control signal, a driving signal, a data signal, etc., to the drive IC DIC. The main board MB may be a printed circuit board, but is not limited thereto.

The main board MB may be connected to the display panel 100 through the flexible film COF in the second non-display area NDA2. The main board MB may be provided as a plurality of main boards along the second non-display area NDA2, but is not limited thereto. The number of main boards MB may vary according to a design.

At least one of the main boards MB may be disposed around the notch NCP and connected to the display panel 100 through the flexible film COF in the notch non-display area N_NDA.

The flexible film COF may be connected to the display panel 100 and the main board MB. The flexible film COF may be attached to each of the display panel 100 and the main board MB and electrically connected to each of the display panel 100 and the main board MB. That is, the display panel 100 and the main board MB may be electrically connected through the flexible film COF. The flexible film COF may be provided as a plurality of flexible films, but is not limited thereto.

The flexible film COF may be attached to the display panel 100 in the second non-display area NDA2. The flexible film COF may be attached to overlap the pad area PA disposed in the non-display area NDA, but is not limited thereto. The flexible film COF may be repeatedly disposed along the second non-display area NDA2. The flexible film COF may be attached to the display panel 100 across the notch non-display area N_NDA and the extension non-display area E_NDA.

A single main board MB may be electrically connected to the display panel 100 through at least one flexible film COF. For example, the main boards MB disposed at both ends among the plurality of main boards MB disposed along the second non-display area NDA2 may be electrically connected to the display panel 100 through one flexible film COF, and the remaining main boards MB may be electrically connected to the display panel 100 through two flexible films COF.

The flexible film COF may be electrically connected to the pad area PA. Accordingly, the flexible film COF may supply a gate control signal, driving signals, power voltages, data voltages, etc. to the plurality of sub-pixels SP (or the pixels) that are disposed in the display area DA and the gate driving unit GIP.

The flexible film COF may be a flexible insulating film. The flexible film COF may include, for example, polycarbonate, polyethylene terephthalate, polyimide, polyamide, polyester, polyacrylate, polymethyl methacrylate, etc., but is not limited thereto.

The drive IC DIC may be mounted on the flexible film COF. The drive IC DIC may be disposed by a method of a chip on glass, a chip on film, a tape carrier package, etc. according to amounting method. In the present disclosure, the drive IC DIC is described as being mounted on the flexible film COF by the chip on film method, but is not limited thereto.

The drive IC DIC may drive the display apparatus 1. The drive IC DIC may process data signals for displaying an image, various driving signals for processing the data signals, etc. The drive IC DIC may include a gate driver IC, a data driver IC, etc.

The gate line GL may extend from the gate driving unit GIP and may be connected to the sub-pixel SP (or the pixel). The gate line GL may electrically connect the gate driving unit GIP to the sub-pixel SP (or the pixel). The gate line GL may apply a gate signal to each sub-pixel SP (or the pixel) from the gate driving unit GIP.

The display panel 100 may further include the gate control line GCL. The gate control line GCL may be disposed in the non-display area NDA. The gate control line GCL may extend from the pad area PA to the gate driving unit GIP and may be electrically connected to the gate driving unit GIP.

The gate control line GCL may apply the gate control signal to the gate driving unit GIP. The gate control signal may be transmitted from the main board MB or the drive IC DIC. The gate control line GCL may electrically connect the gate driving unit GIP to the main board MB or the drive IC DIC.

The gate control line GCL may be electrically connected to the flexible film COF disposed at both ends among the plurality of flexible films COF connected to the display panel 100 along the second non-display area NDA2. The gate control line GCL may be disposed at an outermost edge among a plurality of lines connected to one flexible film COF, but is not limited thereto.

The data line DL may extend from the pad area PA and may be connected to the sub-pixel SP (or the pixel) of the display area DA. The data line DL may apply a data signal to each sub-pixel SP (or each pixel). The data signal may be applied from the main board MB or the drive IC DIC. The data line DL may electrically connect the sub-pixel SP (or the pixel) to the main board MB or the drive IC DIC.

The data line DL may include a first data line DL1 and a second data line DL2. The data line DL may be connected to the data pads DP1 and DP2. The first data line DL1 may be electrically connected in contact with the first data pad DP1 through a first data contact hole CNT1. The second data line DL2 may be electrically connected in contact with the second data pad DP2 through a second data contact hole CNT2.

The low-potential voltage line VSSL may be disposed in the non-display area NDA. The low-potential voltage line VSSL may be disposed across the first non-display area NDA1, and the second non-display area NDA2. The low-potential voltage line VSSL may be disposed in the non-display area NDA to surround the display area DA.

The low-potential voltage line VSSL may be disposed in the non-display area NDA with the display area DA and the gate driving unit GIP interposed therebetween. That is, the gate driving unit GIP may be disposed between the display area DA and the low-potential voltage line VSSL.

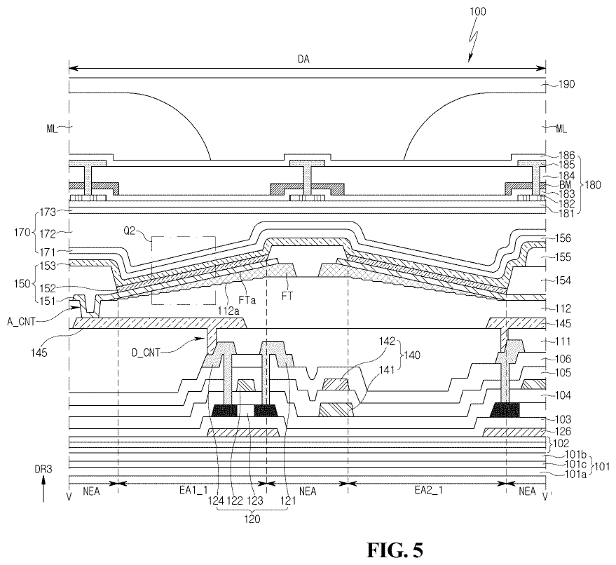

The low-potential voltage line VSSL may apply a low-potential voltage to the sub-pixel SP (or the pixel). The low-potential voltage line VSSL may be electrically connected to a cathode electrode 153 (see FIG. 5) of the sub-pixel SP (or the pixel) to apply a low-potential voltage.

The low-potential voltage line VSSL may be connected to the pad area PA. The low-potential voltage line VSSL may be physically connected to the low-potential voltage pad VSSP and electrically connected to the low-potential voltage pad VSSP.

The low-potential voltage line VSSL and the low-potential voltage pad VSSP may be integrally formed, but are not limited thereto. The low-potential voltage line VSSL may be formed of the same metal layer as the low-potential voltage pad VSSP, but is not limited thereto.

The high-potential voltage line VDDL may be disposed between the display area DA and the low-potential voltage line VSSL. The high-potential voltage line VDDL may apply a high-potential voltage to the sub-pixel SP (or the pixel). The high-potential voltage line VDDL may be electrically connected to an anode electrode 151 (see FIG. 5) of the sub-pixel SP (or the pixel) to apply a high-potential voltage.

The high-potential voltage line VDDL may be connected to the pad area PA. The high-potential voltage line VDDL may be physically connected to the high-potential voltage pad VDDP and electrically connected to the high-potential voltage pad VDDP.

The high-potential voltage line VDDL may contact the high-potential voltage pad VDDP by a high-potential contact hole S_CNT. However, the embodiments of the present specification are not limited thereto. However, the high-potential voltage line VDDL may be formed integrally with the high-potential voltage pad VDDP. In this case, the high-potential voltage line VDDL may include the same material as the high-potential voltage pad VDDP, and the high-potential voltage line VDDL and the high-potential voltage pad VDDP are formed together by the same mask process.

The display apparatus 1 may further include a dam part DMP. The dam part DMP may be disposed in the non-display area NDA. The dam part DMP may be disposed to surround the display area DA, but is not limited thereto. At least a part of the dam part DMP may be disposed to overlap the low-potential voltage line VSSL. The dam part DMP may be disposed between the display area DA and the pad area PA in the second non-display area NDA2.

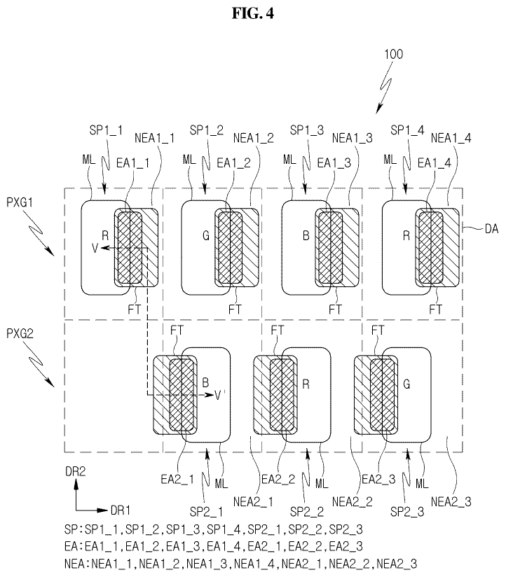

FIG. 4 is a plan view illustrating a pixel arrangement of a display panel according to one embodiment. The plan view of FIG. 4 is an enlarged view illustrating a part of the display area DA in which the pixels are disposed.

Referring to FIG. 4, the display panel 100 may include a first pixel group PXG1 and a second pixel group PXG2.

The first pixel group PXG1 and the second pixel group PXG2 may be disposed in the display area DA.

Each of the first pixel group PXG1 and the second pixel group PXG2 may be disposed repeatedly in the first direction DR1. The first pixel group PXG1 and the second pixel group PXG2 may be disposed alternately and repeatedly in the second direction DR2.

A pixel includes a plurality of a sub-pixel SP. The sub-pixel SP may include a 1_1 sub-pixel SP1_1, a 1_2 sub-pixel SP1_2, a 1_3 sub-pixel SP1_3, a 1_4 sub-pixel SP1_4, a 2_1 sub-pixel SP2_1, a 2_2 sub-pixel SP2_2, and a 2_3 sub-pixel SP2_3.

The first pixel group PXG1 may include the 1_1 sub-pixel SP1_1, the 1_2 sub-pixel SP1_2, the 1_3 sub-pixel SP1_3, and the 1_4 sub-pixel SP1_4. The 1_1 sub-pixel SP1_1, the 1_2 sub-pixel SP1_2, the 1_3 sub-pixel SP1_3, and the 1_4 sub-pixel SP1_4 may be disposed in a row in the first direction.

The 1_1 sub-pixel SP1_1 may emit red (R) light, the 1_2 sub-pixel SP1_2 may emit green (G) light, the 1_3 sub-pixel SP1_3 may emit blue (B) light, and the 1_4 sub-pixel SP1_4 may emit red (R) light.

The 1_1 sub-pixel SP1_1, the 1_2 sub-pixel SP1_2, the 1_3 sub-pixel SP1_3, and the 1_4 sub-pixel SP1_4 may include light-emitting areas EA1_1, EA1_2, EA1_3, and EA1_4, and non-light-emitting areas NEA1_1, NEA1_2, NEA1_3, and NEA1_4 disposed around the light-emitting areas EA1_1, EA1_2, EA1_3, and EA1_4, respectively.

The 1_1 sub-pixel SP1_1 may include a 1_1 light-emitting area EA1_1, and a 1_1 non-light-emitting area NEA1_1 disposed around the 1_1 light-emitting area EA1_1.

The 1_2 sub-pixel SP1_2 may include a 1_2 light-emitting area EA1_2, and a 1_2 non-light-emitting area NEA1_2 disposed around the 1_2 light-emitting area EA1_2.

The 1_3 sub-pixel SP1_3 may include a 1_3 light-emitting area EA1_3, and a 1_3 non-light-emitting area NEA1_3 disposed around the 1_3 light-emitting area EA1_3.

The 1_4 sub-pixel SP1_4 may include a 1_4 light-emitting area EA1_4, and a 1_4 non-light-emitting area NEA1_4 disposed around the 1_4 light-emitting area EA1_4.

The second pixel group PXG2 may include the 2_1 sub-pixel SP2_1, the 2_2 sub-pixel SP2_2, and the 2_3 sub-pixel SP2_3. The 2_1 sub-pixel SP2_1, the 2_2 sub-pixel SP2_2, and the 2_3 sub-pixel SP2_3 may be disposed in a row in the second direction.

The 2_1 sub-pixel SP2_1 may emit blue (B) light, the 2_2 sub-pixel SP2_2 may emit red (R) light, and the 2_3 sub-pixel SP2_3 may emit green (G) light.

The 2_1 sub-pixel SP2_1, the 2_2 sub-pixel SP2_2, and the 2_3 sub-pixel SP2_3 may include light-emitting areas EA2_1, EA2_2, and EA2_3, and non-light-emitting areas NEA2_1, NEA2_2, and NEA2_3 disposed around the light-emitting areas EA2_1, EA2_2, and EA2_3.

The 2_1 sub-pixel SP2_1 may include a 2_1 light-emitting area EA2_1, and a 2_1 non-light-emitting area NEA2_1 disposed around the 2_1 light-emitting area EA2_1.

The 2_2 sub-pixel SP2_2 may include a 2_2 light-emitting area EA2_2, and a 2_2 non-light-emitting area NEA2_2 disposed around the 2_2 light-emitting area EA2_2.

The 2_3 sub-pixel SP2_3 may include a 2_3 light-emitting area EA2_3, and a 2_3 non-light-emitting area NEA2_3 disposed around the 2_3 light-emitting area EA2_3.

In a plan view, no sub-pixel may be disposed below (at the other side in the second direction DR2 of) the 1_1 sub-pixel SP1_1.

In a plan view, the 2_1 sub-pixel SP2_1 may be disposed below (at the other side in the second direction DR2 of) the 1_2 sub-pixel SP1_2.

In a plan view, the 2_2 sub-pixel SP2_2 may be disposed below (at the other side in the second direction DR2 of) the 1_3 sub-pixel SP1_3.

In a plan view, the 2_3 sub-pixel SP2_3 may be disposed below (at the other side in the second direction DR2) the 1_4 sub-pixel SP1_4.

The sub-pixel SP (see FIG. 1) illustrated in FIG. 1 may refer to one of the 1_1 sub-pixel SP1_1, the 1_2 sub-pixel SP1_2, the 1_3 sub-pixel SP1_3, the 1_4 sub-pixel SP1_4, the 2_1 sub-pixel SP2_1, the 2_2 sub-pixel SP2_2, and the 2_3 sub-pixel SP2_3.

A plurality of microlenses ML may each be respectively disposed on one of the 1_1 sub-pixel SP1_1, the 1_2 sub-pixel SP1_2, the 1_3 sub-pixel SP1_3, the 1_4 sub-pixel SP1_4, the 2_1 sub-pixel SP2_1, the 2_2 sub-pixel SP2_2, and the 2_3 sub-pixel SP2_3. The microlens ML may be disposed in each sub-pixel SP (SP1_1, SP1_2, SP1_3, SP1_4, SP2_1, SP2_2, or SP2_3).

One microlens ML is illustrated as being disposed in each sub-pixel SP, but the embodiments of the present specification are not limited thereto. For example, according to a design of each sub-pixel SP, the microlens ML disposed in each sub-pixel SP may be provided as two or more microlenses. When an opening (the light-emitting areas EA) formed in one sub-pixel SP is provided as a plurality of openings, the microlens ML may be disposed in each opening, or a plurality of microlenses ML may be disposed in one opening.

Each sub-pixel SP (SP1_1, SP1_2, SP1_3, SP1_4, SP2_1, SP2_2, or SP2_3) may include the light-emitting area EA (EA1_1, EA1_2, EA1_3, EA1_4, EA2_1, EA2_2, or EA2_3) and the non-light-emitting area NEA (NEA1_1, NEA1_2, NEA1_3, NEA1_4, NEA2_1, NEA2_2, or NEA2_3) disposed around the light-emitting area EA.

In the sub-pixel SP of each of the first pixel group PXG1 and the second pixel group PXG2, at least one of the plurality of organic films and inorganic films disposed on the display panel 100 may be tilted around the light-emitting area EA. That is, at least one of the plurality of organic films and inorganic films may have an inclined surface and may be inclined in different directions in the first pixel group PXG1 and the second pixel group PXG2.

Light emitted from the first pixel group PXG1 and the second pixel group PXG2 may travel in different directions. For example, the light emitted from the first pixel group PXG1 may travel to the other side in the first direction DR1 in a plan view, and the light emitted from the second pixel group PXG2 may travel to one side in the first direction DR1 in a plan view. Accordingly, a user may receive different images according to a location.

The display panel 100 may further include a planarization layer FT. The planarization layer FT may be disposed in the display area DA. The planarization layer FT may not be disposed in the non-display area NDA, but is not limited thereto.

The planarization layer FT may be disposed in the light-emitting area EA of each sub-pixel SP and around the light-emitting area EA. The planarization layer FT may be disposed to extend to the non-light-emitting area NEA of an adjacent sub-pixel according to a design, but is not limited thereto.

The planarization layer FT may be disposed on an inclined surface of at least one of the plurality of organic films and inorganic films. The planarization layer FT may planarize the inclined surface included in at least one of the plurality of organic films and inorganic films.

The planarization layer FT may be disposed to cover and planarize the inclined surface of at least one of the plurality of organic films and inorganic films and disposed to have an inclined surface on the inclined surface of at least one of the plurality of organic films and inorganic films.

Accordingly, even when at least one of the plurality of organic films and inorganic films has an inclined surface, the inclined surface may be planarized further through the planarization layer FT, thereby enabling more smooth deposition of another component disposed on the inclined surface.

Hereinafter, a cross-sectional structure of the display area DA of the display panel 100 including the sub-pixel SP (SP1_1, SP1_2, SP1_3, SP1_4, SP2_1, SP2_2, and SP2_3) will be described with reference to FIG. 5.

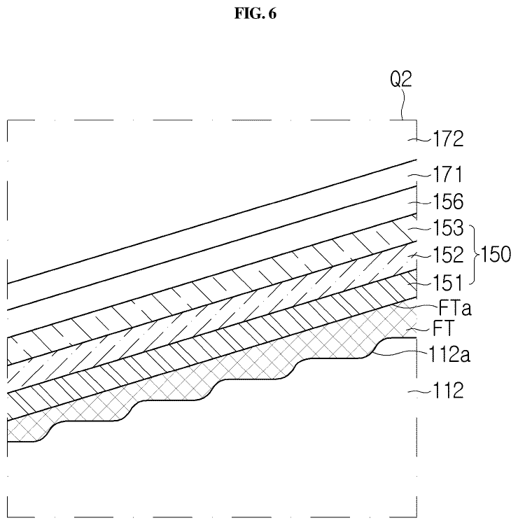

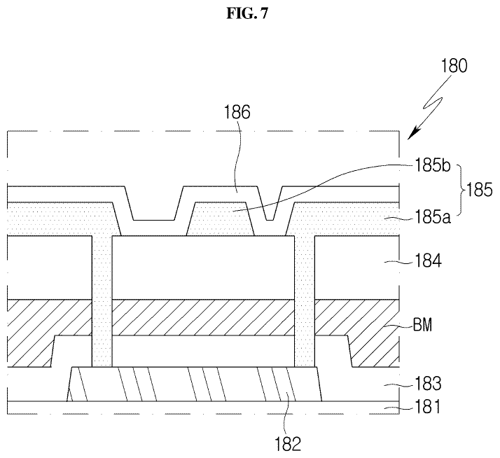

FIG. 5 is a cross-sectional view along line V-V′ in FIG. 4 according to one embodiment. FIG. 6 is an enlarged view of area Q2 in FIG. 5 according to one embodiment. FIG. 7 is a cross-sectional view of a touch part of FIG. 5 taken at a different angle according to one embodiment.

Referring to FIGS. 4 to 7, the display panel 100 may include the substrate 101, the thin film transistor 120, the storage electrode 140, the light-emitting part 150 (e.g., a light-emitting element), the encapsulation part 170, the touch part 180, etc. However, the embodiments of the present specification are not limited thereto.

The substrate 101 may provide a space in which various components may be disposed thereon. The substrate 101 may correspond to the flat surface shape of the display panel 100 of FIG. 1. That is, the substrate 101 may include the notch NCP. The substrate 101 may include the display area DA and the non-display area NDA of the display panel 100 in substantially the same manner.

The substrate 101 may include one or more plastic materials, but is not limited thereto, and may include a glass material.

The substrate 101 may be a multi-substrate including a plurality of substrates having a first substrate 101a, a second substrate 101b, and a third substrate 103c each including a plastic material, such as polyimide, but the embodiments of the present specification are not limited thereto. For example, the substrate 101 may be a single substrate formed of a single layer.

The substrate 101 may include a rigid substrate. However, the embodiments of the present specification are not limited thereto, and the substrate 101 may include a flexible substrate.

The buffer layer 102 may be disposed on the substrate 101. The buffer layer 102 can minimize or delay the diffusion of moisture or oxygen penetrating the substrate 101. The buffer layer 102 may be formed by alternately stacking silicon nitride (SiNₓ) and silicon oxide (SiOₓ) at least once, but the embodiments of the present specification are not limited thereto.

In one embodiment, the buffer layer 102 is formed as multiple layers including three layers, but the number of layers forming the buffer layer 102 is not limited thereto, and the buffer layer 102 may be formed as a single layer.

A light-shielding layer 126 may be disposed on the buffer layer 102. The light-shielding layer 126 can prevent light from being transmitted to a semiconductor layer 123 of the thin film transistor 120. For example, the semiconductor layer 123 may be disposed to overlap the light-shielding layer 126. The light-shielding layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present specification are not limited thereto.

A first insulating layer 103 may be disposed on the light-shielding layer 126. The first insulating layer 103 can prevent a short circuit between a component of the thin film transistor 120 and the light-shielding layer 126. The first insulating layer 103 may be formed of the same material as the buffer layer 102, but the embodiments of the present specification are not limited thereto. For example, the first insulating layer 103 may be formed of an inorganic material, such as silicon nitride (SiNₓ) or silicon oxide (SiOₓ), but the embodiments of the present specification are not limited thereto.

The thin film transistor 120 may be disposed on the first insulating layer 103. The thin film transistor 120 may include a source electrode 121, a gate electrode 122, a semiconductor layer 123, and a drain electrode 124.

The semiconductor layer 123 may be disposed on the first insulating layer 103. The semiconductor layer 123 may include a metal oxide semiconductor, such as indium-gallium-zinc oxide (IGZO), and a silicon-based semiconductor material, such as amorphous silicon or polycrystalline silicon, but the embodiments of the present specification are not limited thereto. The semiconductor layer 123 may include a source area, a drain area, and a channel area between the source area and the drain area.

Since the polycrystalline semiconductor layer has higher mobility than the amorphous semiconductor layer and the oxide semiconductor layer, power consumption can be less, and reliability can be excellent. Accordingly, a driving transistor may be formed of a polycrystalline semiconductor layer, but the embodiments of the present specification are not limited thereto.

A second insulating layer 104 may be disposed on the semiconductor layer 123. The second insulating layer 104 may be formed of the same material as the first insulating layer 103, but the embodiments of the present specification are not limited thereto. The second insulating layer 104 can prevent a short circuit between the semiconductor layer 123 and another component of the thin film transistor 120.

The gate electrode 122 may be disposed on the second insulating layer 104. The gate electrode 122 may be disposed on the second insulating layer 104 to overlap the channel area of the semiconductor layer 123. The gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or a compound thereof, but the embodiments of the present specification are not limited thereto. The gate electrode 122 may be disposed along with the gate line, but the embodiments of the present specification are not limited thereto.

A third insulating layer 105 may be disposed on the gate electrode 122. The third insulating layer 105 may be formed of the same material as the first insulating layer 103 or the second insulating layer 104, but the embodiments of the present specification are not limited thereto.

The storage electrode 140 may be disposed to be spaced apart from the thin film transistor 120. The storage electrode 140 may include a first storage electrode 141 and a second storage electrode 142.

The first storage electrode 141 may be formed of the same material as the gate electrode 122 and formed on the same layer as the gate electrode 122, but the embodiments of the present specification are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be formed of the same material as the first storage electrode 141, but the embodiments of the present specification are not limited thereto.

A fourth insulating layer 106 may be disposed on the second storage electrode 142. The fourth insulating layer 106 may be formed of the same material as the first insulating layer 103, the second insulating layer 104, or the third insulating layer 105, but the embodiments of the present specification are not limited thereto.

The source electrode 121 and the drain electrode 124 may be disposed on the fourth insulating layer 106.

The source electrode 121 and the drain electrode 124 may be electrically connected to the semiconductor layer 123 through contact holes. The source electrode 121 and the drain electrode 124 may be formed of a metallic material. For example, the source electrode 121 and the drain electrode 124 may be formed of a single layer or multiple layers made of one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The source electrode 121 and the drain electrode 124 may be disposed along with the data line. For example, the data line may be formed of the same material as the source electrode 121 and the drain electrode 124 and formed on the same layer, but the embodiments of the present specification are not limited thereto.

The thin film transistor 120 may be a driving transistor, and although not illustrated, the display panel 100 may further include a switching transistor, but the embodiments of the present specification are not limited thereto.

A first protective layer 111 (e.g., a first planarization layer) may be disposed on the source electrode 121 and the drain electrode 124. The first protective layer 111 may be disposed on the thin film transistor 120.

The first protective layer 111 may planarize an upper portion of the thin film transistor 120 and protect the thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present specification are not limited thereto.

The second protective layer 112 may be disposed on the first protective layer 111. The second protective layer 112 may be formed of the same material as the first protective layer 111, but the embodiments of the present specification are not limited thereto.

A connection electrode 145 may be disposed between the first protective layer 111 and the second protective layer 112.

The connection electrode 145 may be disposed between the thin film transistor 120 and the light-emitting part 150.

The connection electrode 145 may electrically connect the thin film transistor 120 to the light-emitting part 150 between the thin film transistor 120 and the light-emitting part 150. The connection electrode 145 may be formed of the same material as the source electrode 121 and the drain electrode 124, but the embodiments of the present specification are not limited thereto.

The connection electrode 145 may contact the drain electrode 124 through a contact hole D_CNT formed in the first protective layer 111 and may be electrically connected to the drain electrode 124.

The connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but the embodiments of the present specification are not limited thereto.

The planarization layer FT may be disposed on the second protective layer 112. The planarization layer FT may cover the inclined surface of the second protective layer 112. The planarization layer FT may include polyimide (PI), but is not limited thereto. The planarization layer FT may serve to planarize the tilted inclined surface of the second protective layer 112. The inclined surface may be tilted or angled with respect to the upper surface of the first protective layer 111 for example.

A thickness of the planarization layer FT may vary from one side to the other side. A part of the planarization layer FT may be thicker from one side to the other side, and the remaining parts may be thinner from one side to the other side. That is, a thickness of a first side of the planarization layer FT is larger than a thickness of a second side of the planarization layer FT that is opposite the first side of the planarization layer.

For example, the planarization layer FT (e.g., a first planarization layer FT) disposed in the 1_1 sub-pixel SP1_1 (the 1_1 light-emitting area EA1_1 and a periphery thereof) may be thicker from the left side to the right side in a cross-sectional view. The planarization layer FT (e.g., a second planarization layer) disposed in the 2_1 sub-pixel SP2_1 (the 2_1 light-emitting area EA2_1 and a periphery thereof) may be thicker from the right side to the left side in a cross-sectional view.

Accordingly, the anode electrode 151 may be tilted more smoothly.

The light-emitting part 150 may be disposed on the planarization layer FT. The light-emitting part 150 may include the anode electrode 151, an organic layer 152, and the cathode electrode 153. The light-emitting part 150 may be an organic light emitting element.

The anode electrode 151 may be disposed on the planarization layer FT. Specifically, the anode electrode 151 overlaps the portion of the planarization layer FT that is angled or tilted with respect to the upper surface of the first protective layer 111. In one embodiment, the anode electrode 151 is in direct contact with an upper surface of the planarization layer FT that is angled or tilted with respect to the upper surface of the first protective layer 111. The anode electrode 151 may be electrically connected to the thin film transistor 120 through a contact hole formed in the second protective layer 112.

The anode electrode 151 may be a reflective electrode that reflects light, but the embodiments of the present specification are not limited thereto. The anode electrode 151 may include a metallic material with high reflectivity, such as a stacking structure (Ti/AlTi) of aluminum (Al) and titanium (Ti), a stacking structure (ITO/AV/ITO) of aluminum (Al) and indium tin oxide (ITO), or an APC alloy and may be formed of a single layer or multiple layers, but the embodiments of the present specification are not limited thereto.

For example, the cathode electrode 153 may include a material, such as indium tin oxide (ITO) or indium zinc oxide (IZO), but the embodiments of the present specification are not limited thereto.

The anode electrode 151 may come into contact with the connection electrode 145 through an anode contact hole A_CNT. The anode electrode 151 may be electrically connected to the connection electrode 145 through the anode contact hole A_CNT. The anode contact hole A_CNT may pass through the second protective layer 112 to expose the connection electrode 145 in an area in which the anode electrode 151 overlaps the connection electrode 145 and may be defined by the second protective layer 112.

The organic layer 152 may be disposed on the anode electrode 151. Specifically, the organic layer 152 is over the portion of the planarization layer FT that is angled or tilted with respect to the upper surface of the first protective layer 111. The organic layer 152 may include one or more light-emitting structures (or light-emitting elements or elements) stacked on the anode electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present specification are not limited thereto. For example, the electron transfer layer may include an electron transporting layer, an electron injecting layer, a hole blocking layer, an n-type charge generation layer, etc., but the embodiments of the present specification are not limited thereto.

The organic layer 152 may be an organic light-emitting layer, an inorganic light-emitting layer, a quantum dot light-emitting layer, a micro light-emitting diode, a micro mini light-emitting diode, etc., but the embodiments of the present specification are not limited thereto. For example, the organic layer 152 of the display panel 100 according to one embodiment of the present specification may include an organic light-emitting layer. The organic layer 152 may be a red light-emitting layer, a green light-emitting layer, and a blue light-emitting layer, but the embodiments of the present specification are not limited thereto. The organic layer 152 may be a white light-emitting layer, but the embodiments of the present specification are not limited thereto.

The cathode electrode 153 may be disposed on the organic layer 152. Specifically, a portion of the cathode electrode 153 is over the portion of the planarization layer FT that is angled or tilted with respect to the upper surface of the first protective layer 111. The cathode electrode 153 may be a transparent electrode that transmits light, but the embodiments of the present specification are not limited thereto. For example, the cathode electrode 153 may include a transparent conductive material, such as indium tin oxide (ITO) or indium zinc oxide (IZO), or a metal that transmits visible light, but the embodiments of the present specification are not limited thereto.

A capping layer 156 may be further disposed on the cathode electrode 153. The capping layer 156 can minimize or at least reduce damage to the cathode electrode 153 of the light-emitting element and the organic layers 152 located below the cathode electrode 153 from an external light source. The capping layer 156 may be formed of an organic or inorganic film.

The capping layer 156 may be disposed using a material, such as LiF or the like, as an inorganic film and may further include an organic film, but the embodiments of the present specification are not limited thereto. For example, the capping layer 156 may be formed of the stacking structure of an organic film and an inorganic film, and a thickness of the organic film may differ from a thickness of the inorganic film. In this case, the thickness of the organic film may be greater than the thickness of the inorganic film. As another example, the capping layer 156 may be formed of two or more layers by stacking materials having different refractive indexes. Accordingly, it is possible to increase the light efficiency of the display panel 100.

A bank 154 may be disposed to expose the anode electrode 151. The bank 154 may define the opening (or the light-emitting area EA) of the sub-pixel SP and may be disposed to cover an edge of the anode electrode 151. The organic layer 152 may be disposed in the opening of the sub-pixel SP. That is, the organic layer 152 may be disposed on the anode electrode 151 exposed by the bank 154.

The bank 154 may be formed of a material containing black pigment, or an organic material, such as a benzocyclobutene resin, a polyimide resin, an acrylic resin, a photosensitive polymer, etc., but the embodiments of the present specification are not limited thereto. When the bank 154 is formed of a material containing black pigment or black dye, the bank 154 may be an opaque bank. When the bank 154 is formed of a material containing black pigment or black dye, it is possible to shield external light or light reflected from the outside, thereby further increasing the luminance of the display apparatus.

A spacer 155 may be further disposed on the bank 154. The spacer 155 may be formed of the same material as the bank 154, but the embodiments of the present specification are not limited thereto. The spacer 155 can prevent or at least reduce sagging of a mask during a mask process, thereby suppressing or preventing stabbing and scratching defects, etc. of the display panel 100.

The encapsulation part 170 may be disposed on the bank 154 or the light-emitting part 150. The encapsulation part 170 may include one or more insulating layers. For example, the encapsulation part 170 may include a first inorganic encapsulation layer 171, an organic encapsulation layer 172 formed on the first inorganic encapsulation layer 171, and a second inorganic encapsulation layer 173 formed on the organic encapsulation layer 172. The encapsulation part 170 may include one or more inorganic layers and one or more organic layers. For example, the first inorganic encapsulation layer 171 and the second inorganic encapsulation layer 173 may include an inorganic material, and the organic encapsulation layer 172 may include an organic material, but the embodiments of the present specification are not limited thereto.

The organic encapsulation layer 172 may end inside the dam part DMP. That is, the organic encapsulation layer 172 may be disposed inside an area surrounded by the dam part DMP without extending beyond the dam part DMP.

The touch part 180 may be disposed on the encapsulation part 170. The touch part 180 may include a touch buffer layer 181, a first touch electrode 182, a first touch insulating layer 183, a black matrix BM, a second touch insulating layer 184, a second touch electrode 185, and a third touch insulating layer 186.

The touch buffer layer 181 may be disposed on the encapsulation part 170. For example, the touch buffer layer 181 may be disposed on the second inorganic encapsulation layer 173. The touch buffer layer 181 may be formed of the same material as the buffer layer 102, but the embodiments of the present specification are not limited thereto.

The first touch electrode 182 may be disposed on the touch buffer layer 181.

The first touch insulating layer 183 may be disposed on the first touch electrode 182. The first touch insulating layer 183 may be formed of silicon oxide (SiOₓ), silicon nitride (SiNₓ), or multiple layers thereof, but the embodiments of the present specification are not limited thereto.

The black matrix BM may be disposed on the first touch insulating layer 183. The black matrix BM may include materials capable of absorbing light. The black matrix BM may include a black pigment or dye, but is not limited thereto. The black matrix BM can prevent a light leakage defect, etc. that may occur between the sub-pixels SP.

The second touch insulating layer 184 may be disposed on the black matrix BM. The second touch insulating layer 184 may include an organic insulation material. For example, the second touch insulating layer 184 may be formed of photo acryl, benzocyclobutene (BCB), polyimide (PI), or polyamide (PA), but is not limited thereto.

The second touch electrode 185 may be disposed on the second touch insulation layer 184. The second touch electrode 185 may include a touch electrode 185a extending in the first direction DR1 and a touch electrode 185b extending in the second direction DR2 different from the first direction.

The first touch electrode 182 may be electrically connected to a touch electrode 185a through a contact hole formed in the second touch insulating layer 184. For example, the touch electrode 185a and the first touch electrode 182 may extend in the first direction DR1.

The first touch electrode 182 and the second touch electrode 185 may include a metallic material. For example, the second touch electrode (e.g., the sensor electrode) 185 and the first touch electrode (e.g., the bridge electrode) 182 may be formed of titanium (Ti), nickel (Ni), aluminum (Al), or an alloy thereof and formed of a triple layer, such as titanium (Ti)/aluminum (Al)/titanium (Ti), but the embodiments of the present specification are not limited thereto.

One of the first touch electrode 182 and the second touch electrode 185 may include a function of detecting touch, and the other may include a function of driving touch, but the embodiments of the present specification are not limited thereto.

The third touch insulating layer 186 may be disposed on the second touch electrode 185. The third touch insulating layer 186 may be formed of the same material as the first touch insulating layer 183, but is not limited thereto.

The microlens ML may be disposed on the third touch insulating layer 186. The microlens ML may include a hemispherical or semi-cylindrical shape, but is not limited thereto. The shape of the microlens ML may vary according to the size, shape, etc. of the light-emitting area EA.

In addition, by arranging the microlens ML, it is possible to secure a wide viewing angle characteristic, increase luminance, and prevent light leakage by shielding leaked light, reflected light, etc.

The center of the microlens ML and the center of the light-emitting area EA corresponding thereto may be misaligned. That is, the center of the microlens ML is spaced apart or offset from the center of the light-emitting area EA that is overlapped by the microlens ML. However, since some components of the light-emitting part 150 may be tilted, light emitted from the light-emitting area EA may travel to the microlens ML.

A lens protective film 190 may be disposed on the microlens ML. The lens protective film 190 may include an organic insulation material, but is not limited thereto. The lens protective film 190 may protect the microlens ML by covering the microlens ML.

A refractive index of the lens protective film 190 may be smaller than a refractive index of the microlens ML. Accordingly, due to a difference in refractive indexes between the microlens ML and the lens protective film 190, light that has passed through the microlens ML can be prevented from being reflected toward the substrate 101.

In the area in which the light-emitting part 150 is disposed, at least one of the inorganic film or organic film in which the light-emitting part 150 is disposed may have a tilted inclined surface.

For example, the second protective layer 112 may be formed so that a part of an upper surface thereof has inclination or is inclined at an angle with respect to the upper surface of the first protective layer 111. That is, the second protective layer 112 may include a first inclined surface 112a that is at an angle with respect to the upper surface of the first protective layer 111 such that the first inclined surface 112a is not parallel with the upper surface of the first protective layer 111. The first inclined surface 112a may be formed as a part of the upper surface of the second protective layer 112. The upper surface of the second protective layer 112 may include the first inclined surface 112a. The upper surface of the second protective layer 112 may refer to one surface of the second protective layer 112, which faces the planarization layer FT and the bank 154.

The first inclined surface 112a may face the planarization layer FT. The first inclined surface 112a may be tilted with respect to a thickness direction (third direction DR3) of the display panel 100.

The first inclined surface 112a may be tilted with respect to a lower surface of the second protective layer 112. The lower surface of the second protective layer 112 may refer to one surface facing the first protective layer 111.

The first inclined surface 112a may be tilted with respect to an upper surface of the first protective layer 111. The upper surface of the first protective layer 111 may refer to one surface facing the second protective layer 112.

The first inclined surface 112a may be disposed in the light-emitting area EA of each pixel and may also be disposed partially around the light-emitting area EA, but is not limited thereto.

The planarization layer FT may be disposed on the first inclined surface 112a. In one embodiment, the planarization layer FT is in direct contact with the first inclined surface 112. However, the embodiments of the present specification are not limited thereto, and the planarization layer FT may be further disposed around the first inclined surface 112a.

The planarization layer FT may be formed so that a part of the upper surface thereof has inclination. That is, a portion of the planarization layer FT is angled with respect to the upper surface of the first protective layer 111. That is, the planarization layer FT may include a second inclined surface FTa. The second inclined surface FTa may be formed as a part of the upper surface of the planarization layer FT. The upper surface of the planarization layer FT may refer to one surface of the planarization layer FT, which faces the anode electrode 151 and the bank 154. The second inclined surface FTa is in contact with the anode electrode 151 and the bank 154.

The second inclined surface FTa may face the anode electrode 151. The second inclined surface FTa may be tilted with respect to the thickness direction (the third direction DR3) of the display panel 100.

The second inclined surface FTa may be tilted with respect to the lower surface of the second protective layer 112. The lower surface of the second protective layer 112 may refer to one surface facing the first protective layer 111.

The second inclined surface FTa may be tilted with respect to the upper surface of the first protective layer 111. The upper surface of the first protective layer 111 may refer to one surface facing the second protective layer 112. In one embodiment, the angle of the tilt of the second inclined surface FTa with respect to the upper surface of the first protective layer 111 is dependent on the magnitude of the offset between the center of the microlens ML and the center of the emission area of the subpixel that partially overlaps the microlens ML.

The second inclined surface FTa may be disposed in the light-emitting area EA of each pixel and may also be disposed partially around the light-emitting area EA, but is not limited thereto.

As the planarization layer FT is disposed on the first inclined surface 112a of the second protective layer 112, the first inclined surface 112a may be planarized.

The second protective layer 112 and the planarization layer FT may have the tilted inclined surface in the light-emitting area EA. That is, at least a part of the first inclined surface 112a may be disposed in the light-emitting area EA. At least a part of the second inclined surface FTa may be disposed in the light-emitting area EA.

The first inclined surface 112a may include an uneven surface that is more uneven compared to the second inclined surface FTa of the planarization layer FT. That is, the second inclined surface FTa of the planarization layer FT is smooth compared to the uneven surface of the first inclined surface 112a. The first inclined surface 112a may include a concave (i) portion and a convex (n) portion based on the second protective layer 112. The concave portion and the convex portion may be provided as a plurality of concave portions and convex portions and disposed alternately and repeatedly.

The planarization layer FT may be disposed on the first inclined surface 112a to cover the uneven surface of the first inclined surface 112a, and the second inclined surface FTa may be formed to be flatter than the first inclined surface 112a.

A surface roughness of the first inclined surface 112a may be greater than a surface roughness of the second inclined surface FTa. That is, the surface roughness of the second inclined surface FTa is less than the surface roughness of the first inclined surface 112a such that the second inclined surface FTa is smoother than the first inclined surface 111a. Here, the surface roughness may refer to a degree of unevenness of each inclined surface 112a or FTa. That is, the concave portion of the first inclined surface 112a from an average line of the first inclined surface 112a may be more concave than the concave portion of the second inclined surface FTa from an average line of the second inclined surface FTa, and the convex portion of the first inclined surface 112a from the average line of the first inclined surface 112a may be more convex than the convex portion of the second inclined surface FTa from the average line of the second inclined surface FTa.

Even when the first inclined surface 112a is formed in the second protective layer 112 and has the uneven surface, the planarization layer FT may be disposed on the second protective layer 112 to maintain the inclined surface and form a flatter inclined surface (the second inclined surface FTa).

Since the planarization layer FT is disposed on the first inclined surface 112a of the second protective layer 112, the second inclined surface FTa may be disposed on the first inclined surface 112a, and the anode electrode 151 may be disposed on the second inclined surface FTa. Since the anode electrode 151 is disposed on the second inclined surface FTa that is flatter than the first inclined surface 112a, the deposition of the anode electrode 151 can be performed more smoothly.

Accordingly, it is possible to reduce defects during the process of depositing the anode electrode 151 and suppress or prevent a defect of the anode electrode 151 in the display apparatus 1. Furthermore, it is possible to increase the life of the display apparatus 1 and reduce the production energy of the display apparatus 1.

The light-emitting part 150 may be disposed on the second inclined surface FTa of which at least a part is inclined. At least a part of each of the anode electrode 151, the organic layer 152, and the cathode electrode 153 that are disposed on the second inclined surface FTa may be tilted.

Each of the anode electrode 151, the organic layer 152, and the cathode electrode 153 may be tilted with respect to the upper surface of the first protective layer 111 or with respect to the substrate 101.

At least a part of each of the anode electrode 151, the organic layer 152, and the cathode electrode 153 may be tilted in a direction toward the microlens ML. Accordingly, light emitted from the light-emitting area EA may travel toward the microlens ML.

Specifically, at least a part of each of the anode electrode 151, the organic layer 152, and the cathode electrode 153 may be disposed on the second inclined surface FTa. Each of the anode electrode 151, the organic layer 152, and the cathode electrode 153 may be disposed entirely on the tilted second inclined surface FTa, but is not limited thereto.

The anode electrode 151 and the organic layer 152 that are disposed on the second inclined surface FTa may be disposed to be inclined (tilted) corresponding to the second inclined surface FTa. Accordingly, a part of the cathode electrode 153 disposed on the organic layer 152 may be disposed to be inclined.

For example, the anode electrode 151 and the organic layer 152 may be disposed to be inclined in the thickness direction (the third direction DR3) of the display panel 100 in the 1_1 light-emitting area EA1_1, the 2_1 light-emitting area EA2_1, and surrounding areas thereof. A direction in which the upper surface of the anode electrode 151 and the upper surface of the organic layer 152 face each other may be tilted with respect to the thickness direction (the third direction DR3) of the display panel 100.

In the 1_1 light-emitting area EA1_1, the 2_1 light-emitting area EA2_1, and peripheries thereof, directions in the anode electrode 151 and the organic layer 152 are tilted may be different.

In FIG. 5, the anode electrode 151 and the organic layer 152 around the 1_1 light-emitting area EA1_1 of the 1_1 sub-pixel SP1_1 and the 2_1 light-emitting area EA2_1 of the 2_1 sub-pixel SP2_1 have been described, but the descriptions thereof may be applied to all of the sub-pixels SP.

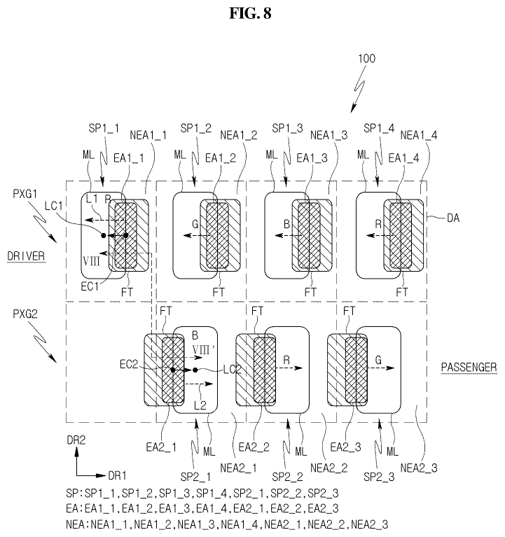

Accordingly, light emitted from each sub-pixel SP may be inclined in the thickness direction (the third direction DR3) of the display panel 100. The description thereof will be given with reference to FIGS. 8 and 9.

FIG. 8 is a plan view of a display panel according to one embodiment. FIG. 9 is a cross-sectional view along line VIII-VIII′ in FIG. 8 according to one embodiment. FIGS. 8 and 9 are schematic views that are substantially the same as FIGS. 4 and 5, respectively, but illustrate paths of light L1 and 12 emitted from the light-emitting part 150.

Referring to FIGS. 8 and 9, the microlens ML and the light-emitting area EA corresponding thereto may be misaligned. Specifically, a center of the microlens ML and a center of the light-emitting area EA may be misaligned so that the center of the microlens ML and the center of the light-emitting area EA are spaced apart from each other.

A center EC1 of the 1_1 light-emitting area EA1_1 of the 1_1 sub-pixel SP1_1 and a center LC1 of the microlens ML disposed on the 1_1 sub-pixel SP1_1 may be misaligned so as to be spaced apart from each other. In a plan view, the center LC1 of the microlens ML may be misaligned from the center EC1 of the 1_1 light-emitting area EA1_1 to the other side (left side in a plan view) in the first direction DR1. That is, the center LC1 of the microlens ML is offset from the center EC1 of the 1_1 light-emitting area EA1_1 in a first direction along direction DR1 in the plan view such that the center LC1 of the microlens ML is to the left of the center EC1 of the 1_1 light-emitting area EA1_1.

The description of the misalignment of the 1_1 sub-pixel SP1_1 may be applied to the remaining sub-pixels SP1_2, SP1_3, and SP1_4 of the first pixel group PXG1 in the substantially the same manner. However, in each of the sub-pixels SP1_1, SP1_2, SP1_3, and SP1_4 of the first pixel group PXG1, the degree of misalignment between the microlens ML and the light-emitting area EA may be different.

However, the embodiments of the present specification are not limited thereto, and a direction in which the center LC1 of the microlens ML and the center EC1 of the 1_1 light-emitting area EA1_1 are misaligned may vary according to a design.

A center EC2 of the 2_1 light-emitting area EA2_1 of the 2_1 sub-pixel SP2_1 and a center LC2 of the microlens ML disposed on the 2_1 sub-pixel SP2_1 may be misaligned. In a plan view, the center LC2 of the microlens ML may be misaligned from the center EC2 of the 2_1 light-emitting area EA2_1 to one side (right side in a plan view) in the first direction DR1. That is, the center LC2 of the microlens ML is offset from the center EC2 of the 2_1 light-emitting area EA2_1 in a second direction along direction DR1 in the plan view such that the center LC2 of the microlens ML is to the right of the center EC2 of the 2_1 light-emitting area EA2_1.

The description of the misalignment of the 2_1 sub-pixel SP2_1 may be applied to the remaining sub-pixels SP2_2 and SP2_3 of the second pixel group PXG2 in the substantially the same manner. However, in each of the sub-pixels SP2_1, SP2_2, and SP2_3 of the second pixel group PXG2, the degree of misalignment between the microlens ML and the light-emitting area EA may be different.

However, the embodiments of the present specification are not limited thereto, and a direction in which the center LC2 of the microlens ML and the center EC2 of the 2_1 light-emitting area EA2_1 are misaligned may vary according to a design.

The opening (or the light-emitting area EA) of the sub-pixel SP and the light-emitting part 150 disposed around the opening may be disposed to be tilted with respect to the thickness direction (the third direction DR3), and the light L1 and L2 emitted from the light-emitting part 150 may travel in a direction tilted with respect to the thickness direction (the third direction DR3).

As the microlens ML and the light-emitting area EA are misaligned, even when the light L1 and L2 emitted from the light-emitting part 150 travels while being tilted with respect to the thickness direction (the third direction DR3), each light L1 or L2 may travel toward the microlens ML. As shown in FIG. 9, the left light-emitting part 150 is tilted at a first angle with respect to an upper surface of the first protective layer 111 such that the light L1 is emitted at the first angle towards the left positioned microlens L1 that is closer to the driver than the passenger. Similarly, the right light-emitting part 150 is tilted at a second angle with respect to the upper surface of the first protective layer 111 that is different from the first angle such that the light L2 is emitted at the second angle towards the right positioned microlens L2 that is closer to the passenger than the driver.

The sub-pixels SP1_1, SP1_2, SP1_3, and SP1_4 disposed in the first pixel group PXG1 may emit the light L1 to the left (the other side in the first direction DR1) in a plan view. The sub-pixels SP2_1, SP2_2, and SP2_3 disposed in the second pixel group PXG2 may emit the light L2 to the right (one side in the first direction DR1) in a plan view.

That is, the light L1 emitted from the sub-pixels SP1_1, SP1_2, SP1_3, and SP1_4 of the first pixel group PXG1 may travel while tilted to the other side in the first direction DR1 with respect to the thickness direction (the third direction DR3). The light L2 emitted from the sub-pixels SP2_1, SP2_2, and SP2_3 of the second pixel group PXG2 may travel while tilted to one side in the first direction DR1 with respect to the thickness direction (the third direction DR3).

The direction and degree of misalignment of the microlens ML and the light-emitting area EA may vary according to the traveling direction of the light emitted from the sub-pixels SP of each pixel group PXG1 or PXG2.

In a plan view, the sub-pixels SP1_1, SP1_2, SP1_3, and SP1_4 disposed in the first pixel group PXG1 and the sub-pixels SP2_1, SP2_2, and SP2_3 disposed in the second pixel group PXG2 may emit light in different directions, and thus a screen displayed to a driver DRIVER sitting in the driver's seat may be distinguished from a screen displayed to a passenger PASSENGER sitting in the passenger's seat so that each may be controlled separately, and different screens may be displayed to the driver DRIVER and the passenger PASSENGER.

Hereinafter, a cross-sectional structure of the non-display area NDA of the display apparatus 1 will be described. The same content as that described in the cross-sectional structure of the display area DA will be briefly described or omitted.

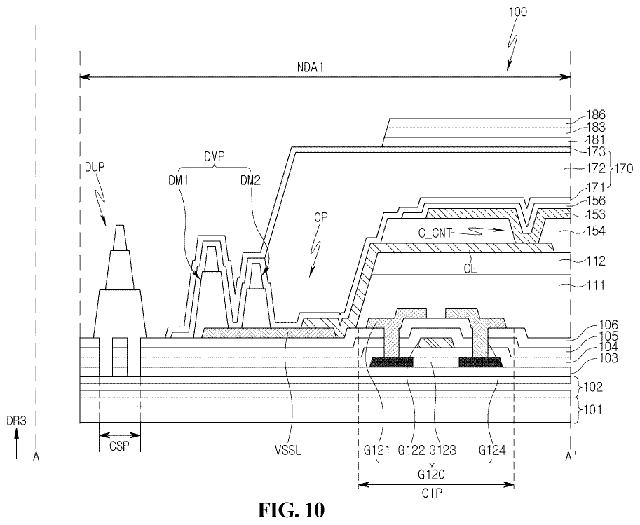

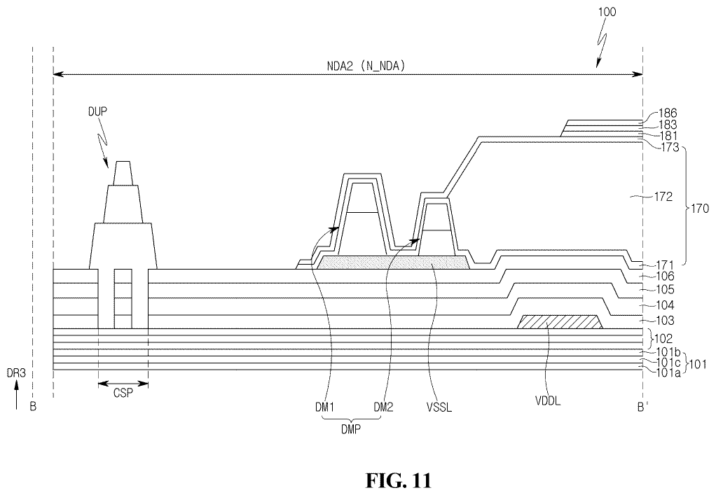

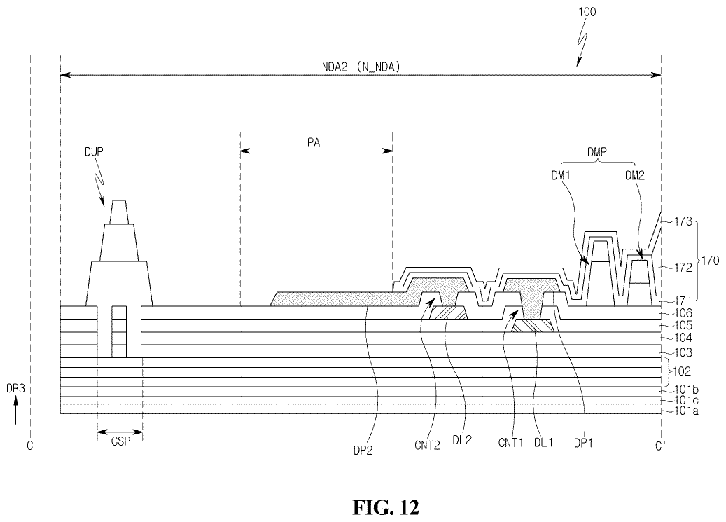

FIG. 10 is a cross-sectional view along line A-A′ in FIG. 1 according to one embodiment. FIG. 11 is a cross-sectional view along line B-B′ in FIG. 3 according to one embodiment. FIG. 12 is a cross-sectional view along line C-C′ in FIG. 3 according to one embodiment.

FIG. 10 illustrates a cross-sectional structure of the first non-display area NDA1. FIGS. 11 and 12 illustrate cross-sectional structures of the second non-display area NDA2. FIGS. 11 and 12 illustrate cross sections of the notch non-display area N_NDA of the second non-display area NDA2, but the descriptions thereof may be applied to the extension non-display area E_NDA in the substantially the same manner.

Referring to FIGS. 1, 3, 5, and 10 to 12, in the display area DA and the non-display area NDA, the display panel 100 may include the substrate 101, the buffer layer 102, the first insulating layer 103, the second insulating layer 104, the third insulating layer 105, the fourth insulating layer 106, the first protective layer 111, the second protective layer 112, the bank 154, the encapsulation part 170, the touch buffer layer 181, the first touch insulating layer 183, and the third touch insulating layer 186 that are sequentially disposed.

In the first non-display area NDA1, the display panel 100 may further include the gate control transistor G120, the low-potential voltage line VSSL, the dam part DMP, a plurality of pads VSSP, VDDP, and DP disposed in the pad area PA, the data line DL (DL1 and DL2), and a crack prevention pattern CSP.

The gate control transistor G120 may have substantially the same configuration as the thin film transistor 120 of the sub-pixel SP and may be formed together by the same process as the thin film transistor 120 of the sub-pixel SP, but is not limited thereto.

The gate control transistor G120 may include a control source electrode G121, a control gate electrode G122, a control semiconductor layer G123, and a control drain electrode G124.

The light-shielding layer 126 may be further disposed under the gate control transistor G120. One of the control source electrode G121 and the control drain electrode G124 may be electrically connected in contact with the light-shielding layer 126, but is not limited thereto.

The low-potential voltage line VSSL may be disposed on the fourth insulating layer 106. The low-potential voltage line VSSL may be formed of the same metal layer as the source electrode 121 and the drain electrode 124 of the thin film transistor 120, but is not limited thereto.

The display panel 100 may further include a low-potential connection electrode CE. The low-potential connection electrode CE may connect the low-potential voltage line VSSL to the cathode electrode 153.

The low-potential connection electrode CE may be disposed on the second protective layer 112. The bank 154 may be disposed on the low-potential connection electrode CE. The low-potential connection electrode CE may be disposed on the same layer as the anode electrode 151 and may include the same material as the anode electrode 151, and the low-potential connection electrode CE and the anode electrode 151 may be formed together using one mask by the same process, but the embodiments of the present specification are not limited thereto.

The display panel 100 may further include an exposed part OP. The exposed part OP may expose at least a part of the low-potential voltage line VSSL by recessing the first protective layer 111 and the second protective layer 112.

The exposed part OP may be defined by the first protective layer 111 and the second protective layer 112. The exposed part OP may be defined by a side surface of the first protective layer 111, a side surface of the second protective layer 112, and a side surface of a second dam DM2.

The low-potential connection electrode CE may be electrically connected in contact with the low-potential voltage line VSSL exposed in the exposed part OP. At least a part of the low-potential connection electrode CE may be disposed on the second protective layer 112 and may extend from the second protective layer 112 toward the low-potential voltage line VSSL.

The low-potential connection electrode CE may be further disposed on the side surface of the first protective layer 111 that defines the exposed part OP and the side surface of the second protective layer 112 and may be further disposed on the fourth insulating layer 106 and the low-potential voltage line VSSL that are exposed by the exposed part OP. Accordingly, the low-potential connection electrode CE may come into contact with the low-potential voltage line VSSL.

The low-potential connection electrode CE may be electrically connected to the cathode electrode 153. The low-potential connection electrode CE and the cathode electrode 153 may be electrically connected in contact with each other through a low-potential contact hole C_CNT in an overlapping area. The low-potential contact hole C_CNT may be defined by passing through the bank 154 in the area in which the low-potential connection electrode CE and the cathode electrode 153 overlap each other and may expose the low-potential connection electrode CE.

The dam part DMP may include a first dam DM1 and a second dam DM2. The first dam DM1 and the second dam DM2 may overlap the low-potential voltage line VSSL.

In the second non-display area NDA2, the first dam DM1 and the second dam DM2 may overlap the low-potential voltage line VSSL. In the first non-display area NDA1, the first dam DM1 and the second dam DM2 may overlap the low-potential voltage line VSSL.

The first dam DM1 may be disposed outside the second dam DM2, but is not limited thereto.

The first dam DM1 may be formed in a multilayered structure. Each layer of the first dam DM1 may include the same material as the second protective layer 112 and the bank 154, and each layer of the first dam DM1, the second protective layer 112, and the bank 154 may be formed together using one mask by the same process, but the embodiments of the present specification are not limited thereto.

The second dam DM2 may be formed in a multilayered structure. Each layer of the second dam DM2 may include the same material as the bank 154 and the spacer 155, and each layer of the second dam DM2, the bank 154, and the spacer 155 may be formed together using one mask by the same process, but the embodiments of the present specification are not limited thereto.

The crack prevention pattern CSP may be disposed at an outermost edge of the non-display area NDA. The crack prevention pattern CSP may be defined by recessing at least one of the inorganic films disposed on the substrate 101.

For example, the crack protection pattern CSP may be defined by recessing the first insulating layer 103, the second insulating layer 104, the third insulating layer 105, and the fourth insulating layer 106, but is not limited thereto.

A crack dummy pattern DUP may be further disposed on the crack protection pattern CSP. The crack dummy pattern DUP may fil the recessed crack protection pattern CSP. The crack dummy pattern DUP may be formed of multiple layers. For example, the crack dummy pattern DUP may be formed of three layers. Layers of the crack dummy pattern DUP may include the same material as the first protective layer 111, the second protective layer 112, and the bank 154.

The high-potential voltage line VDDL may be disposed on the buffer layer 102 and covered by the first insulating layer 103. The high-potential voltage line VDDL may include the same material as the light-shielding layer 126, and the high-potential voltage line VDDL and the light-shielding layer 126 may be formed together using one mask by the same process, but the embodiments of the present specification are not limited thereto.

Although not illustrated, the high-potential voltage pad VDDP may be disposed on the same layer as the source electrode 121 and the drain electrode 124, may include the same material as the source electrode 121 and the drain electrode 124, and may be formed together using one mask by the same process as the source electrode 121 and the drain electrode 124, but is not limited thereto.

In this case, the high-potential voltage pad VDDP may be electrically connected in contact with the high-potential voltage line VDDL through the high-potential contact hole S_CNT that exposes the high-potential voltage line VDDL.

However, the embodiments of the present specification are not limited thereto, and the high-potential voltage line VDDL may be disposed on the same layer as the source electrode 121 and the drain electrode 124 and may include the same material as the source electrode 121 and the drain electrode 124, and the high-potential voltage line VDDL, the source electrode 121, and the drain electrode 124 may be formed together using one mask by the same process.

The first data pad DP1 and the second data pad DP2 may be disposed on the fourth insulating layer 106. The first data pad DP1 and the second data pad DP2 may be disposed on the same layer as the source electrode 121 and the drain electrode 124, may include the same material as the source electrode 121 and the drain electrode 124, and may be formed together using one mask by the same process as the source electrode 121 and the drain electrode 124, but are not limited thereto.

The first data line DL1 may be disposed on the second insulating layer 104 and covered by the third insulating layer 105. The first data line DL1 may include the same material as the gate electrode 122 and may be formed together using one mask by the same process as the gate electrode 122, but is not limited thereto.

The second data line DL2 may be disposed on the third insulating layer 105 and covered by the fourth insulating layer 106. The second data line DL2 may include the same material as the second storage electrode 142 and may be formed together using one mask by the same process as the second storage electrode 142, but is not limited thereto.

The first data line DL1 may be electrically connected in contact with the first data pad DP1 through the first data contact hole CNT1. The second data line DL2 may be electrically connected in contact with the second data pad DP2 through the second data contact hole CNT2.

The crack prevention pattern CSP may be disposed outside the pad area PA. The crack prevention pattern CSP may be disposed between the ends of the pad area PA and the non-display area NDA2.

However, the plurality of pads VSSP, VDDP, and DP may not be covered by a plurality of inorganic films. The plurality of inorganic films disposed on the fourth insulating layer 106 may expose the plurality of pads VSSP, VDDP, and DP. The plurality of inorganic films disposed on the fourth insulating layer 106 may not be disposed in the pad area PA.

Accordingly, the flexible film COF may be configured so that at least a part thereof is disposed to overlap the pad area PA and attached to the display panel 100, and the flexible film COF may be electrically connected in contact with the plurality of pads VSSP, VDDP, and DP of the pad area PA.

Hereinafter, other embodiments of the present specification will be described. For contents substantially the same as those described with reference to FIGS. 1 to 12 among components included in other embodiments, the same reference numerals are given, and the overlapping contents may be omitted or briefly described.

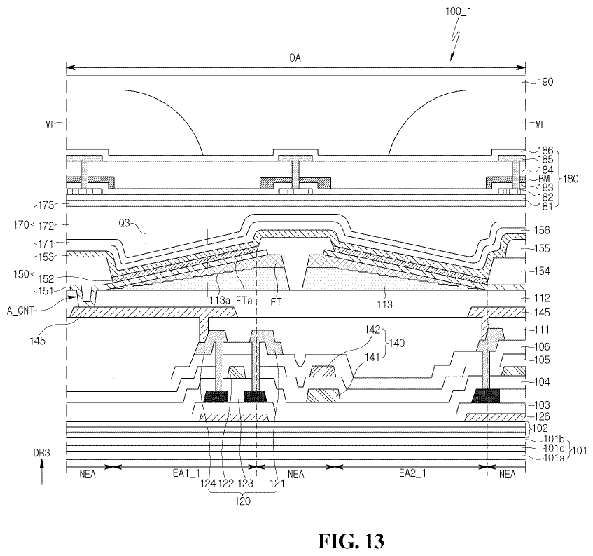

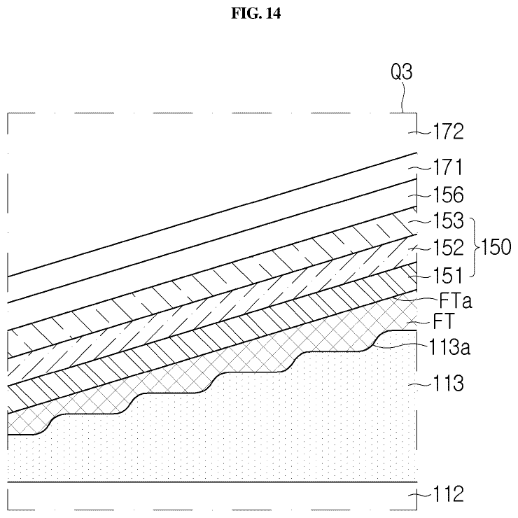

FIG. 13 is a cross-sectional view of a display apparatus according to another embodiment. FIG. 14 is an enlarged view of area Q3 in FIG. 13 according to one embodiment.

FIG. 13 illustrates a cross section of a display panel 100_1 of a display apparatus according to another embodiment.

Referring to FIGS. 13 and 14, the display panel 100_1 according to the present embodiment may further include a third protective layer 113.

The third protective layer 113 may be disposed between the second protective layer 112 and the planarization layer FT. The third protective layer 113 may be disposed to overlap the planarization layer FT. The entire area of the third protective layer 113 may overlap the planarization layer FT, but is not limited thereto.

The third protective layer 113 may be formed of the same material as the second protective layer 112, but is not limited thereto. The third protective layer 113 may be patterned and formed on the second protective layer 112. The third protective layer 113 may be formed in a plurality of island shapes, but is not limited thereto.

The third protective layer 113 may be disposed in the display area DA. The third protective layer 113 may not be disposed in the non-display area NDA, but is not limited thereto.

The third protective layer 113 may be disposed on the second protective layer 112, and the planarization layer FT may be disposed on the third protective layer 113. The upper surface of the second protective layer 112 may not include an inclined surface. The second protective layer 112 may not include an inclined surface in an area in which the planarization layer FT or the third protective layer 113 is disposed.

The third protective layer 113 may include a third inclined surface 113a. The third inclined surface 113a may be formed as a part of an upper surface of the third protective layer 113. The upper surface of the third protective layer 113 may refer to one surface of the third protective layer 113, which faces the planarization layer FT and the bank 154.

The third inclined surface 113a may face the planarization layer FT. The third inclined surface 113a may be tilted with respect to the thickness direction (the third direction DR3) of the display panel 100.

The third inclined surface 113a may be tilted with respect to a lower surface of the third protective layer 113. The lower surface of the third protective layer 113 may refer to one surface facing the first protective layer 111.

The third inclined surface 113a may be tilted with respect to the upper surface of the second protective layer 112. The upper surface of the second protective layer 112 may refer to one surface facing the third protective layer 113.

The third inclined surface 113a may be tilted with respect to the upper surface of the first protective layer 111. The upper surface of the first protective layer 111 may refer to one surface facing the third protective layer 113.

The third inclined surface 113a may be disposed in the light-emitting area EA of each pixel and may also be disposed partially around the light-emitting area EA, but is not limited thereto.

The planarization layer FA may be disposed on the third inclined surface 113a. However, the embodiments of the present specification are not limited thereto, and the planarization layer FA may be further disposed around the third inclined surface 113a.

As the planarization layer FT is disposed on the third inclined surface 113a of the third protective layer 113, the third inclined surface 113a may be planarized.

The third inclined surface 113a may include an uneven surface. The third inclined surface 113a may include a concave ( [symbol] ) portion and a convex ( [symbol] ) portion based on the third protective layer 113. The concave portion and the convex portion may be provided as a plurality of concave portions and convex portions and disposed alternately and repeatedly.

The planarization layer FT may be disposed on the third inclined surface 113a to cover the uneven surface of the third inclined surface 113a, and the second inclined surface FTa may be formed to be flatter than the third inclined surface 113a.

The third protective layer 113 and the planarization layer FT may have the tilted inclined surface in the light-emitting area EA. That is, at least a part of the third inclined surface 113a may be disposed in the light-emitting area EA. At least a part of the second inclined surface FTa may be disposed in the light-emitting area EA.

Surface roughness of the third inclined surface 113a may be greater than surface roughness of the second inclined surface FTa. Here, the surface roughness may refer to a degree of unevenness of each inclined surface 113a or FTa. That is, the concave portion of the third inclined surface 113a from an average line of the third inclined surface 113a may be more concave than the concave portion of the second inclined surface FTa from an average line of the second inclined surface FTa, and the convex portion of the third inclined surface 113a from the average line of the third inclined surface 113a may be more convex than the convex portion of the second inclined surface FTa from the average line of the second inclined surface FTa.

Even when the third inclined surface 113a is formed in the third protective layer 113 and has the uneven surface, the planarization layer FT may be disposed on the third protective layer 113 to maintain the inclined surface and form a flatter inclined surface (the second inclined surface FTa).

Since the planarization layer FT is disposed on the third inclined surface 113a of the third protective layer 113, the second inclined surface FTa may be disposed on the third inclined surface 113a, and the anode electrode 151 may be disposed on the second inclined surface FTa. Since the anode electrode 151 is disposed on the second inclined surface FTa that is flatter than the third inclined surface 113a, the deposition of the anode electrode 151 can be performed more smoothly.

Even in this case, it is possible to reduce defects during the process of depositing the anode electrode 151 and suppress or prevent defects of the anode electrode 151 in the display apparatus. In addition, it is possible to increase the life of the display apparatus and reduce the production energy of the display apparatus.

In addition, it is possible to improve the reliability of the process by forming each of the second protective layer 112 that defines the anode contact hole A_CNT and the third protective layer 113 including the third inclined surface 113a through different mask processes.

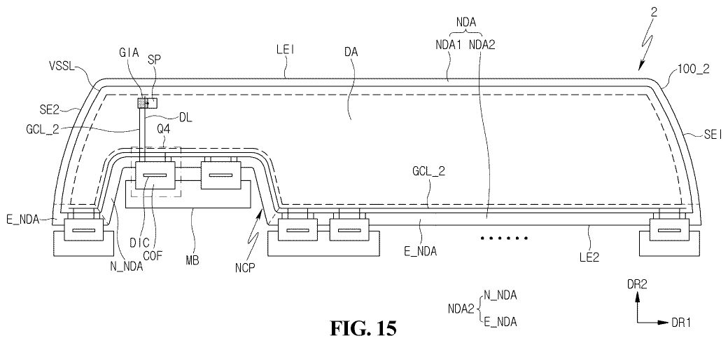

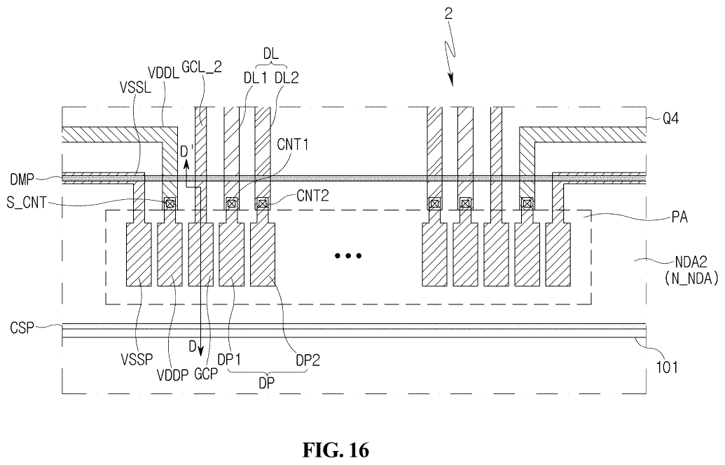

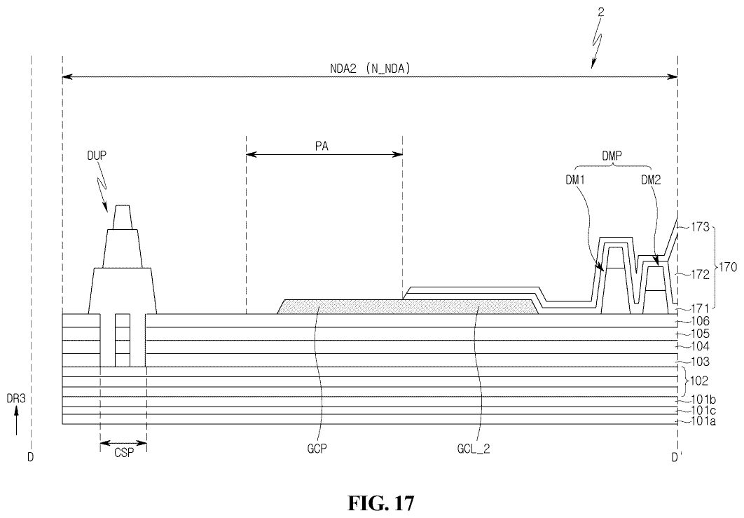

FIG. 15 is a plan view of a display apparatus according to still another embodiment. FIG. 16 is an enlarged view of area Q4 in FIG. 15 according to one embodiment. FIG. 17 is a cross-sectional view along line D-D′ in FIG. 16 according to one embodiment.

FIG. 16 is a view of area Q4 of a display apparatus 2 according to another embodiment, from which the flexible film COF, the main board MB, and the drive IC DIC are omitted.

Referring to FIGS. 15 to 17, in the display apparatus 2 according to the present embodiment, the gate driving unit GIP (see FIG. 1) may not separately be disposed in the non-display area NDA, and a pixel gate driving unit GIA may be disposed in the display area DA.

The pixel gate driving unit GIA may be provided as a plurality of pixel gate driving units, and each pixel gate driving unit GIA may be connected to each of the plurality of sub-pixels SP. The pixel gate driving unit GIA may be disposed around the sub-pixel SP. The pixel gate driving unit GIA may be disposed between adjacent sub-pixels SP.

For example, the pixel gate driving unit GIA may be disposed between the adjacent sub-pixels SP in the first direction DR1. The sub-pixel SP and the pixel gate driving unit GIA may be alternately repeatedly disposed in the first direction DR1. The sub-pixel SP may be continuously and repeatedly disposed in the second direction DR2. The pixel gate driving unit GIA may be continuously repeatedly disposed in the second direction DR2.

The pixel gate driving unit GIA may perform substantially the same role as the gate driving unit GIP (see FIG. 1). The pixel gate driving unit GIA may include at least one transistor.

The pixel gate driving unit GIA may be electrically connected to an adjacent sub-pixel SP.

The pixel gate driving unit GIA may receive a gate control signal from the drive IC DIC through a gate control line GCL_2. The pixel gate driving unit GIA may generate a scan signal and a light-emitting signal (or a light-emitting control signal) based on the gate control signal. Accordingly, the driving of the adjacent sub-pixel SP may be controlled.

Since the pixel gate driving unit GIA is disposed in the display area DA, it is possible to minimize the non-display area NDA or the bezel area, thereby providing improved aesthetic feeling to a user.

The display apparatus 2 may further include the gate control line GCL_2 and a gate control pad GCP.

The gate control line GCL_2 may be disposed in the non-display area NDA and the display area DA. The gate control line GCL_2 may be disposed in the second non-display area NDA2, but is not limited thereto. The gate control line GCL_2 may be disposed in an extension direction of the second non-display area NDA2.

The gate control line GCL_2 may be partially disposed in the second non-display area NDA2 and may extend from the second non-display area NDA2 to the pixel gate driving unit GIA of the display area DA. The gate control line GCL_2 may be electrically connected to the plurality of pixel gate driving units GIAs disposed in the display area DA.

The gate control pad GCP may be disposed in the pad area PA. In the pad area PA, the gate control pad GCP is illustrated as being disposed between the high-potential voltage pad VDDP and the data pad DP, but is not limited thereto, and the arrangement location of the gate control pad GCP may vary according to a design.

The gate control pad GCP may include the same material as the gate control line GCL_2, but is not limited thereto. The gate control pad GCP and the gate control line GCL_2 may be formed integrally, but are not limited thereto.

The gate control pad GCP and the gate control line GCL_2 may be disposed on the fourth insulating layer 106. The gate control pad GCP and the gate control line GCL_2 may be disposed on the same layer as the source electrode 121 (see FIG. 5) and the drain electrode 124 (see FIG. 5) and may include the same material as the source electrode 121 and the drain electrode 124, and the gate control pad GCP, the gate control line GCL, the source electrode 121, and the drain electrode 124 may be formed together using one mask by the same process, but the embodiments of the present specification are not limited thereto.

The plurality of pads VSSP, VDDP, DP, and GCP may not be covered by the plurality of inorganic films. The plurality of inorganic films disposed on the fourth insulating layer 106 may expose the plurality of pads VSSP, VDDP, DP, and GCP. The plurality of inorganic films disposed on the fourth insulating layer 106 may not be disposed in the pad area PA.

For example, the first inorganic encapsulation layer 171, the second inorganic encapsulation layer 173, the touch buffer layer 181, the first touch insulating layer 183, and the third touch insulating layer 186 may be disposed up to the end of the substrate 101 in the notch non-display area N_NDA, but may not be disposed in the pad area PA. Accordingly, the plurality of pads VSSP, VDDP, DP, and GCP disposed on the fourth insulating layer 106 may be exposed, and the display panel 1002 may be adhered and electrically connected to the flexible film COF.

FIG. 17 illustrates the cross section of the notch non-display area N_NDA, but the description thereof may be applied to the extension non-display area E_NDA in the same manner.

Since the gate driving unit GIP (see FIG. 1) is omitted from the non-display area NDA and the pixel gate driving unit GIA is disposed in the display area DA, the non-display area NDA can be reduced, thereby reducing the bezel area and increasing the display area DA.

Even in this case, since the planarization layer FT (see FIG. 5) is disposed, it is possible to reduce defects during the process of depositing the anode electrode 151 (see FIG. 5) and suppress or prevent defects in the anode electrode 151 in the display apparatus. In addition, it is possible to increase the life of the display apparatus and reduce the production energy of the display apparatus.

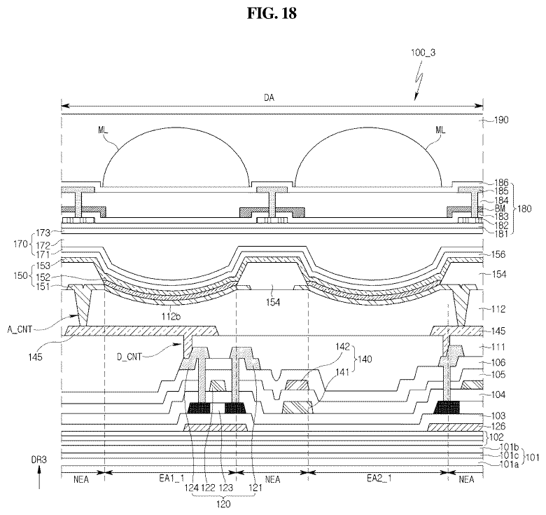

FIG. 18 is a cross-sectional view of the display apparatus according to another embodiment. FIG. 18 illustrates a cross section of a display panel 100_3 of a display apparatus according to yet another embodiment.

Referring to FIG. 18, the display panel 100_3 of the display apparatus according to the present disclosure may include the anode electrode 151 having a concave shape.

Specifically, the second protective layer 112 may be formed so that a part of the upper surface thereof has a concave shape. The second protective layer 112 may include a concave surface 112b. The concave surface 112b may be configured as a part of the upper surface of the second protective layer 112. The upper surface of the second protective layer 112 may include the concave surface 112b.

The concave surface 112b may have a concave shape from the upper surface of the second protective layer 112 toward the lower surface of the second protective layer 112.

At least a part of the anode electrode 151 may be disposed on the concave surface 112b. The anode electrode 151 may have a concave shape toward the lower surface of the second protective layer 112 along the shape of the concave surface 112b.

At least parts of the organic layer 152, the cathode electrode 153, the capping layer 156, and the first inorganic encapsulation layer 171 that are sequentially disposed on the anode electrode 151 may also have a concave shape to correspond to the concave shape of the anode electrode 151.

The concave surface 112b may be disposed in the light-emitting area EA. Accordingly, the anode electrode 151, the organic layer 152, the cathode electrode 153, the capping layer 156, and the first inorganic encapsulation layer 171 may also have a concave shape in the light-emitting area EA, but are not limited thereto.

In this case, the center of the microlens ML may be aligned with the center of the corresponding light-emitting area EA.

Since the anode electrode 151 has a concave shape, it is possible to reduce the range of angles at which light emitted from the light-emitting part 150 is emitted, thereby improving the light-condensing effect of the light emitted from the light-emitting area EA of each sub-pixel SP (see FIG. 4). Furthermore, it is possible to increase luminance of the display apparatus.

Even in this case, the planarization layer FT (see FIG. 5) may be further disposed on the concave surface 112b. Accordingly, it is possible to reduce defects during the process of depositing the anode electrode 151 and suppress or prevent defects of the anode electrode 151 in the display apparatus. In addition, it is possible to increase the life of the display apparatus and reduce the production energy of the display apparatus.

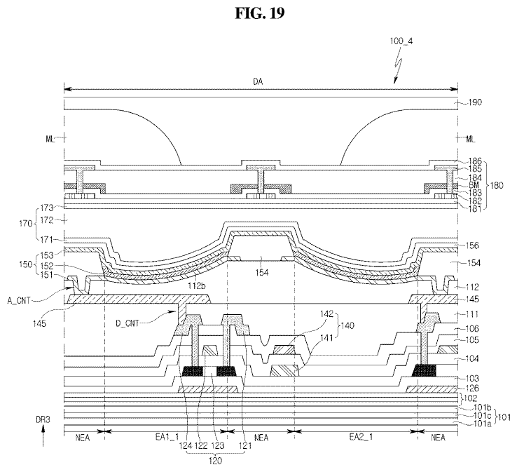

FIG. 19 is a cross-sectional view of a display apparatus according to yet another embodiment. FIG. 19 illustrates a cross section of a display panel 100_4 of a display apparatus according to yet another embodiment.

Referring to FIG. 19, the display panel 100_4 of the display apparatus according to the present disclosure may include the anode electrode 151 having a concave shape, and the anode electrode 151 may be tilted (or inclined).

Specifically, the second protective layer 112 may be formed so that a part of the upper surface thereof has a concave shape. The second protective layer 112 may include a concave surface 112b. The concave surface 112b may be configured as a part of the upper surface of the second protective layer 112. The upper surface of the second protective layer 112 may include the concave surface 112b.

The concave surface 112b may have a concave shape from the upper surface of the second protective layer 112 toward the lower surface of the second protective layer 112.

The concave surface 112b may have a concave shape and may tilted with respect to the thickness direction (the third direction DR3) of the display panel 100_4. For example, in a cross-sectional view, one side end of the concave surface 112b may have a different height from the other side end. In a cross-sectional view, the concave surface 112b may be formed concavely with respect to a virtual flat surface that virtually connects the one side end to the other side end of the concave surface 112b, and the virtual flat surface may be tilted with respect to the lower surface of the second protective layer 112.

At least a part of the anode electrode 151 may be disposed on the concave surface 112b. The anode electrode 151 may have a shape that is concave toward and tilted with respect to the lower surface of the second protective layer 112 along the shape of the concave surface 112b.

At least parts of the organic layer 152, the cathode electrode 153, the capping layer 156, and the first inorganic encapsulation layer 171 that are sequentially disposed on the anode electrode 151 may also have a shape that is concave and tilted to correspond to the concave shape of the anode electrode 151.

The concave surface 112b may be disposed in the light-emitting area EA. Accordingly, the anode electrode 151, the organic layer 152, the cathode electrode 153, the capping layer 156, and the first inorganic encapsulation layer 171 may also have a shape that is concave and tilted in the light-emitting area EA, but are not limited thereto.

The center of the microlens ML and the center of the light-emitting area EA corresponding thereto may be misaligned. The anode electrode 151 may be tilted toward the microlens ML.

Since the anode electrode 151 has a concave shape, it is possible to reduce the range of angles at which light emitted from the light-emitting part 150 is emitted, thereby improving the light-condensing effect of the light emitted from the light-emitting area EA of each sub-pixel SP (see FIG. 4). Furthermore, it is possible to increase luminance of the display apparatus.

In addition, since the anode electrode 151 is tilted, it is possible to suppress or prevent crosstalk between different images emitted by the first pixel group PXG1 (see FIG. 4) and the second pixel group PXG2 (see FIG. 4).

Even in this case, the planarization layer FT (see FIG. 5) may be further disposed on the concave surface 112b. Accordingly, it is possible to reduce defects during the process of depositing the anode electrode 151 and suppress or prevent defects of the anode electrode 151 in the display apparatus. In addition, it is possible to increase the life of the display apparatus and reduce the production energy of the display apparatus.

A display apparatus according to various embodiments of the present specification may be described as follows.

According to one embodiment of the present specification, there is provided a display apparatus including: a substrate including a display area and a non-display area that is around the display area; a thin film transistor on the substrate; a first protective layer on the thin film transistor; a connection electrode on the first protective layer, the connection electrode electrically connected to the thin film transistor through the first protective layer; a second protective layer on the connection electrode, the second protective layer having an upper surface that includes a first inclined surface that is tilted with respect to an upper surface of the first protective layer; a planarization layer on the second protective layer, the planarization layer covering the first inclined surface of the second protective layer; and an anode electrode on the planarization layer such that the anode electrode overlaps the first inclined surface of the second protective layer.

In one embodiment, the first inclined surface of the second protective layer includes an uneven surface that is more uneven than an upper surface of the planarization layer.

In one embodiment, the upper surface of the planarization layer includes a second inclined surface that is tilted with respect to the upper surface of the first protective layer.

In one embodiment, an upper surface of the planarization layer includes a second inclined surface and a surface roughness of the second inclined surface is less than a surface roughness of the first inclined surface.

In one embodiment, the planarization layer is in the display area.

In one embodiment, a thickness of a first side of the planarization layer is larger than a thickness of a second side of the planarization layer that is opposite the first side of the planarization layer.

In one embodiment, the display device further comprises: a first sub-pixel and a second sub-pixel, wherein the planarization layer includes a first planarization layer in the first sub-pixel and a second planarization layer in the second sub-pixel, wherein a thickness of a first side of the first planarization layer in the first sub-pixel is thicker than a thickness of a second side of the first planarization layer that is opposite the first side of the first planarization layer along a first direction and a thickness of a first side of the second planarization layer in the second sub-pixel is thinner than a thickness of a second side of the second planarization layer that is opposite the first side of the second planarization layer along the first direction.

In one embodiment, the display device further comprises: a plurality of pixels in the display area, wherein each of the plurality of pixels includes a light-emitting area and a non-light-emitting area and the planarization layer is disposed across the light-emitting area and the non-light-emitting area.

In one embodiment, the display device further comprises: a bank that covers an edge of the anode electrode, the bank defining a light-emitting area of a pixel in the display area, wherein an upper surface of the planarization layer is tilted in the light-emitting area with respect to the upper surface of the first protective layer.

In one embodiment, an upper surface of the anode electrode is tilted with respect to the upper surface of the first protective layer.

In one embodiment, the display device further comprises: an organic layer on the anode electrode; and a cathode electrode on the organic layer, wherein an upper surface of the organic layer and an upper surface of the cathode electrode are tilted with respect to the upper surface of the first protective layer.

In one embodiment, the display device further comprises: a pad area; and a low-potential voltage line, a high-potential voltage line, and a data line that are electrically connected to the pad area, wherein in the non-display area below the display area, the high-potential voltage line is between the low-potential voltage line and the display area.

In one embodiment, the low-potential voltage line surrounds the display area.

In one embodiment, the non-display area is located at a first side or a second side of the display area further includes a gate driving circuit between the low-potential voltage line and the display area.

In one embodiment, the low-potential voltage line surrounds the display area.

In one embodiment, the non-display area located at a first side or a second side of the display area further includes a gate driving circuit between the low-potential voltage line and the display area.

In one embodiment, the display apparatus further comprises: a pixel gate driving circuit located in the display area; and a gate control line electrically connecting the pad area to the pixel gate driving circuit, wherein the gate control line is between the low-potential voltage line and the display area.

In one embodiment, the first inclined surface of the second protective layer includes a concave surface from an upper surface of the second protective layer toward a lower surface of the second protective layer, and at least a part of the anode electrode is on the concave surface such that the anode electrode has a shape that is concave toward and tilted with respect to the lower surface of the second protective layer along the concave surface.

In one embodiment, a display apparatus comprises: a substrate including a display area and a non-display area that is around the display area; a thin film transistor on the substrate; a first protective layer on the thin film transistor; a connection electrode on the first protective layer, the connection electrode electrically connected to the thin film transistor through the first protective layer; a second protective layer on the connection electrode; a third protective layer on the second protective layer, the third protective layer having an upper surface that includes an inclined surface that is tilted with respect to an upper surface of the first protective layer; a planarization layer on the third protective layer, the planarization layer covering the inclined surface of the third protective layer; and an anode electrode on the planarization layer such that the anode electrode overlaps the inclined surface of the third protective layer.

In one embodiment, the inclined surface of the third protective layer includes an uneven surface that is more uneven than an upper surface of the planarization layer.

In one embodiment, the planarization layer planarizes the uneven surface of the inclined surface.

In one embodiment, the upper surface of the planarization layer includes an inclined surface that is tilted with respect to the upper surface of the first protective layer.

In one embodiment, an upper surface of the planarization layer includes an inclined surface that is tilted with respect to the upper surface of the first protective layer, and a surface roughness of the inclined surface of the planarization layer is less than a surface roughness of the inclined surface of the third protective layer.

In one embodiment, a display apparatus comprises: a substrate including a display area having a first subpixel and a second subpixel; a first thin film transistor included in the first subpixel and a second thin film transistor included in the second subpixel; a first protective layer on the first thin film transistor and the second thin film transistor; a first organic light emitting element of the first subpixel, the first organic light emitting element electrically connected to the first thin film transistor and tilted at a first angle with respect to an upper surface of the first protective layer such that light is emitted by the first organic light emitting element at the first angle; a second organic light emitting element of the second subpixel, the second organic light emitting element connected to the second thin film transistor and tilted at a second angle with respect to the upper surface of the first protective layer such that light is emitted by the second organic light emitting element at the second angle that is different from the first angle.

In one embodiment, the display apparatus further comprises: a first microlens having a center that is offset from a center of a first emission area of the first subpixel along a first direction in a plan view of the display apparatus; and a second microlens having a center that is offset from a center of a second emission area of the second subpixel along a second direction that is opposite the first direction in the plan view, wherein the light emitted at the first angle is emitted to the first microlens and the light emitted at the second angle is emitted to the second microlens.

In one embodiment, the display apparatus further comprises: a second protective layer on the first protective layer, the second protective layer having an upper surface having a first inclined surface that is tilted with respect to the upper surface of the first protective layer and a second inclined surface that is tilted with respect to the upper surface of the first protective layer in a different direction than the first inclined surface; a first planarization layer on the first inclined surface of the second protective layer; and a second planarization layer on the second inclined surface of the second protective layer, wherein the first organic light emitting element is disposed on the first planarization layer such that the first organic light emitting element overlaps the first inclined surface of the second protective layer, and the second organic light emitting element is disposed on the second planarization layer such that the second organic light emitting element overlaps the second inclined surface of the second protective layer.

In one embodiment, the first planarization layer has an upper surface having a surface roughness that is smoother than a surface roughness of the first inclined surface of the second protective layer, and the second planarization layer has an upper surface having a surface roughness that is smoother than a surface roughness of the second inclined surface of the second protective layer.

In one embodiment, the first organic light emitting element includes a first anode electrode that is in direct contact with the upper surface of the first planarization layer and the second organic light emitting element includes a second anode that is in direct contact with the upper surface of the second planarization layer.

In one embodiment, a display apparatus comprises: a substrate including a display area, the display area including a first subpixel having a first emission area and a second subpixel having a second emission area; a first organic light emitting element disposed in the first emission area of the first subpixel; a second organic light emitting element disposed in the second emission area of the second subpixel; a first microlens having a center that is offset from a center of the first emission area of the first subpixel along a first direction in a plan view of the display apparatus; and a second microlens having a center that is offset from a center of the second emission area of the second subpixel along a second direction that is opposite the first direction in the plan view.

Although the embodiments have been described above with reference to the accompanying drawings, those skilled in the art to which the present specification pertains will be able to understand that the above-described technical configuration can be carried out in other specific forms without changing the technical spirit or essential features thereof. Accordingly, it should be understood that the above-described embodiments are illustrative and not restrictive in all respects. In addition, the scope of the embodiments is determined by the appended claims rather than detailed description. In addition, the meaning and scope of the claims and all changed or modified forms derived from the equivalent concept thereof should be construed as being included in the scope of the embodiments.

### DESCRIPTION OF REFERENCE NUMERALS

1: display apparatus
100: display apparatus
111: first protective layer
112: second protective layer
112a: first inclined surface
113: third protective layer
113a: third inclined surface
FT: planarization layer
FTa: second inclined surface
151: anode electrode
152: organic layer
153: cathode electrode
VSSL: low-potential voltage line
GIP: gate driving unit
GIA: pixel gate driving unit
NCP: notch
DA: display area
NDA: non-display area
NDA1: first non-display area
NDA2: second non-display area
N_NDA: notch non-display area
E_NDA: extension non-display area
PA: pad area
SP: sub-pixel
EA: light-emitting area
NEA: non-light-emitting area
ML: microlens

What is claimed is:

1. A display apparatus comprising:
a substrate including a display area and a non-display area that is around the display area;
a thin film transistor on the substrate;
a first protective layer on the thin film transistor;
a connection electrode on the first protective layer, the connection electrode electrically connected to the thin film transistor through the first protective layer;
a second protective layer on the connection electrode, the second protective layer having an upper surface that includes a first inclined surface that is tilted with respect to an upper surface of the first protective layer;
a planarization layer on the second protective layer, the planarization layer covering the first inclined surface of the second protective layer; and
an anode electrode on the planarization layer such that the anode electrode overlaps the first inclined surface of the second protective layer.

2. The display apparatus of claim 1, wherein the first inclined surface of the second protective layer includes an uneven surface that is more uneven than an upper surface of the planarization layer.

3. The display apparatus of claim 2, wherein the upper surface of the planarization layer includes a second inclined surface that is tilted with respect to the upper surface of the first protective layer.

4. The display apparatus of claim 1, wherein an upper surface of the planarization layer includes a second inclined surface and a surface roughness of the second inclined surface is less than a surface roughness of the first inclined surface.

5. The display apparatus of claim 1, wherein the planarization layer is in the display area.

6. The display apparatus of claim 5, wherein a thickness of a first side of the planarization layer is larger than a thickness of a second side of the planarization layer that is opposite the first side of the planarization layer.

7. The display apparatus of claim 1, further comprising:
a first sub-pixel and a second sub-pixel,
wherein the planarization layer includes a first planarization layer in the first sub-pixel and a second planarization layer in the second sub-pixel,
wherein a thickness of a first side of the first planarization layer in the first sub-pixel is thicker than a thickness of a second side of the first planarization layer that is opposite the first side of the first planarization layer along a first direction and a thickness of a first side of the second planarization layer in the second sub-pixel is thinner than a thickness of a second side of the second planarization layer that is opposite the first side of the second planarization layer along the first direction.

8. The display apparatus of claim 6, further comprising:
a plurality of pixels in the display area,
wherein each of the plurality of pixels includes a light-emitting area and a non-light-emitting area and the planarization layer is disposed across the light-emitting area and the non-light-emitting area.

9. The display apparatus of claim 1, further comprising:
a bank that covers an edge of the anode electrode, the bank defining a light-emitting area of a pixel in the display area,
wherein an upper surface of the planarization layer is tilted in the light-emitting area with respect to the upper surface of the first protective layer.

10. The display apparatus of claim 1, wherein an upper surface of the anode electrode is tilted with respect to the upper surface of the first protective layer.

11. The display apparatus of claim 10, further comprising:
an organic layer on the anode electrode; and
a cathode electrode on the organic layer,
wherein an upper surface of the organic layer and an upper surface of the cathode electrode are tilted with respect to the upper surface of the first protective layer.

12. The display apparatus of claim 1, further comprising:
a pad area; and
a low-potential voltage line, a high-potential voltage line, and a data line that are electrically connected to the pad area,
wherein in the non-display area below the display area, the high-potential voltage line is between the low-potential voltage line and the display area.

13. The display apparatus of claim 12, wherein the low-potential voltage line surrounds the display area.

14. The display apparatus of claim 13, wherein the non-display area located at a first side or a second side of the display area further includes a gate driving circuit between the low-potential voltage line and the display area.

15. The display apparatus of claim 13, further comprising:
a pixel gate driving circuit located in the display area; and
a gate control line electrically connecting the pad area to the pixel gate driving circuit,
wherein the gate control line is between the low-potential voltage line and the display area.

16. The display apparatus of claim 1, wherein the first inclined surface of the second protective layer includes a concave surface from an upper surface of the second protective layer toward a lower surface of the second protective layer, and at least a part of the anode electrode is on the concave surface such that the anode electrode has a shape that is concave toward and tilted with respect to the lower surface of the second protective layer along the concave surface.

17. A display apparatus comprising:
a substrate including a display area and a non-display area that is around the display area;
a thin film transistor on the substrate;
a first protective layer on the thin film transistor;
a connection electrode on the first protective layer, the connection electrode electrically connected to the thin film transistor through the first protective layer;
a second protective layer on the connection electrode;
a third protective layer on the second protective layer, the third protective layer having an upper surface that includes an inclined surface that is tilted with respect to an upper surface of the first protective layer;
a planarization layer on the third protective layer, the planarization layer covering the inclined surface of the third protective layer; and
an anode electrode on the planarization layer such that the anode electrode overlaps the inclined surface of the third protective layer.

18. The display apparatus of claim 17, wherein the inclined surface of the third protective layer includes an uneven surface that is more uneven than an upper surface of the planarization layer.

19. The display apparatus of claim 18, wherein the planarization layer planarizes the uneven surface of the inclined surface.

20. The display apparatus of claim 19, wherein the upper surface of the planarization layer includes an inclined surface that is tilted with respect to the upper surface of the first protective layer.

21. The display apparatus of claim 17, wherein an upper surface of the planarization layer includes an inclined surface that is tilted with respect to the upper surface of the first protective layer, and
a surface roughness of the inclined surface of the planarization layer is less than a surface roughness of the inclined surface of the third protective layer.

22. A display apparatus comprising:
a substrate including a display area having a first subpixel and a second subpixel;
a first thin film transistor included in the first subpixel and a second thin film transistor included in the second subpixel;
a first protective layer on the first thin film transistor and the second thin film transistor;
a first organic light emitting element of the first subpixel, the first organic light emitting element electrically connected to the first thin film transistor and tilted at a first angle with respect to an upper surface of the first protective layer such that light is emitted by the first organic light emitting element at the first angle;
a second organic light emitting element of the second subpixel, the second organic light emitting element connected to the second thin film transistor and tilted at a second angle with respect to the upper surface of the first protective layer such that light is emitted by the second organic light emitting element at the second angle that is different from the first angle.

23. The display apparatus of claim 22, further comprising:
a first microlens having a center that is offset from a center of a first emission area of the first subpixel along a first direction in a plan view of the display apparatus; and
a second microlens having a center that is offset from a center of a second emission area of the second subpixel along a second direction that is opposite the first direction in the plan view,
wherein the light emitted at the first angle is emitted to the first microlens and the light emitted at the second angle is emitted to the second microlens.

24. The display apparatus of claim 22, further comprising:
a second protective layer on the first protective layer, the second protective layer having an upper surface having a first inclined surface that is tilted with respect to the upper surface of the first protective layer and a second inclined surface that is tilted with respect to the upper surface of the first protective layer in a different direction than the first inclined surface;
a first planarization layer on the first inclined surface of the second protective layer; and
a second planarization layer on the second inclined surface of the second protective layer,
wherein the first organic light emitting element is disposed on the first planarization layer such that the first organic light emitting element overlaps the first inclined surface of the second protective layer, and the second organic light emitting element is disposed on the second planarization layer such that the second organic light emitting element overlaps the second inclined surface of the second protective layer.

25. The display apparatus of claim 24, wherein the first planarization layer has an upper surface having a surface roughness that is smoother than a surface roughness of the first inclined surface of the second protective layer, and the second planarization layer has an upper surface having a surface roughness that is smoother than a surface roughness of the second inclined surface of the second protective layer.

26. The display apparatus of claim 25, wherein the first organic light emitting element includes a first anode electrode that is in direct contact with the upper surface of the first planarization layer and the second organic light emitting element includes a second anode that is in direct contact with the upper surface of the second planarization layer.

27. A display apparatus comprising:
a substrate including a display area, the display area including a first subpixel having a first emission area and a second subpixel having a second emission area;
a first organic light emitting element disposed in the first emission area of the first subpixel;
a second organic light emitting element disposed in the second emission area of the second subpixel;
a first microlens having a center that is offset from a center of the first emission area of the first subpixel along a first direction in a plan view of the display apparatus; and
a second microlens having a center that is offset from a center of the second emission area of the second subpixel along a second direction that is opposite the first direction in the plan view.
